(19) United States
(12) Patent Application Publication
(10) Pub. No.: US 2026/0018469 A1
(43) Pub. Date: Jan. 15, 2026

(54) SEMICONDUCTOR DEVICE MANUFACTURING METHOD AND SEMICONDUCTOR TESTING DEVICE

(71) Applicant: ROHM CO., LTD., Kyoto-shi (JP)

(72) Inventors: Kei SENGA, Kyoto-shi (JP); Satoru KOMINAMI, Kyoto-shi (JP)

(73) Assignee: ROHM CO., LTD., Kyoto-shi (JP)

(21) Appl. No.: 19/334,986

(22) Filed: Sep. 22, 2025

Related U.S. Application Data
(63) Continuation of application No. PCT/JP2024/012727, filed on Mar. 28, 2024.

(30) Foreign Application Priority Data
Mar. 30, 2023 (JP) 2023-056214

(51) Int. Cl. H01L 21/66; H10D 12/00; H10D 62/10; H10D 62/832

(52) U.S. Cl. CPC H01L 22/14; H10D 12/481; H10D 62/103; H10D 62/8325

(57) ABSTRACT

A semiconductor device manufacturing method including a reverse bias test for a device structure includes a step of applying a reverse bias voltage to the device structure, and a monitor step of monitoring a decrease rate of a leak current of the device structure at a time of applying the reverse bias voltage.

### CROSS-REFERENCE TO RELATED APPLICATIONS

The present application is a bypass continuation of International Patent Application No. PCT/JP2024/012727, filed on Mar. 28, 2024, which claims priority to Japanese Patent Application No. 2023-056214, filed on Mar. 30, 2023, in the Japan Patent Office, and the entire contents of these applications are hereby incorporated herein by reference.

### BACKGROUND

### 1. Field of the Disclosure

The present disclosure relates to a semiconductor device manufacturing method and a semiconductor testing device.

### 2. Description of the Related Art

US2018/0151719A1 discloses a reverse bias test for determining that a silicon carbide semiconductor device has failed based on an increased value of a leak current (see FIG. 8A).

### BRIEF DESCRIPTION OF DRAWINGS

FIG. 1 is a schematic view illustrating a wafer structure according to a first embodiment example.

FIG. 2 is a cross-sectional view of the wafer structure illustrated in FIG. 1.

FIG. 3 is a cross-sectional view illustrating a principal portion of a device structure illustrated in FIG. 1.

FIG. 4 is a schematic diagram of a semiconductor testing device according to a specific embodiment.

FIG. 5 is a schematic diagram illustrating a reverse bias test related to the semiconductor testing device.

FIG. 6 is a cross-sectional view illustrating the reverse bias test together with the device structure.

FIG. 7 is a schematic diagram illustrating a gate bias test related to the semiconductor testing device.

FIG. 8 is a cross-sectional view illustrating the gate bias test together with the device structure.

FIG. 9 is a graph illustrating initial behavior characteristics of a leak current.

FIG. 10 is a cross-sectional view for describing a normal device structure.

FIG. 11 is a cross-sectional view for describing a device structure having a latent defect.

FIG. 12 is a step diagram illustrating an example of a semiconductor device manufacturing method according to a specific embodiment.

FIG. 13 is a step diagram illustrating an example of a latent defect detection step.

FIG. 14 is a step diagram illustrating another example of the method of manufacturing the semiconductor device according to the specific embodiment.

FIG. 15 is a cross-sectional view illustrating a principal portion of a wafer structure according to a second embodiment example.

FIG. 16 is a cross-sectional view illustrating a principal portion of a wafer structure according to a third embodiment example.

FIG. 17 is a cross-sectional view illustrating a principal portion of a wafer structure according to a fourth embodiment example.

FIG. 18 is a cross-sectional view of the wafer structure illustrated in FIG. 17.

FIG. 19 is a cross-sectional view illustrating a wafer structure according to the fifth embodiment example.

### DETAILED DESCRIPTION OF THE PREFERRED EMBODIMENTS

Hereinafter, specific embodiments shall be described in detail with reference to the attached drawings. The attached drawings are all schematic views and are not strictly illustrated, and relative positional relationships, scales, proportions, angles and the like thereof do not always match. Identical reference signs are given to corresponding structures among the attached drawings, and duplicate descriptions thereof shall be omitted or simplified. For the structures whose description has been omitted or simplified, the description given before the omission or simplification shall apply.

When the wording “substantially” is used in the present specification, the wording includes a numerical value (shape) equal to a numerical value (shape) of a comparison target and also includes numerical errors (shape errors) in a range of ±10% with the numerical value (shape) of the comparison target as a reference. Although the wordings “first,” “second,” etc., are used in the following description, these are indicators added to names of respective structures in order to clarify the order of description and are not added with an intention of restricting the names of the respective structures.

In the following description, a “p-type” or an “n-type” is used to indicate a conductivity type of a semiconductor (impurity). However, the “p-type” may be referred to as a “first conductivity type,” and the “n-type” may be referred to as a “second conductivity type.” As a matter of course, the “n-type” may be referred to as a “first conductivity type,” and the “p-type” may be referred to as a “second conductivity type.” The “p-type” is a conductivity type caused by a trivalent element, and the “n-type” is a conductivity type caused by a pentavalent element. The trivalent element is at least one of boron, aluminum, gallium, and indium. The pentavalent element is at least one of nitrogen, phosphorus, arsenic, antimony, and bismuth.

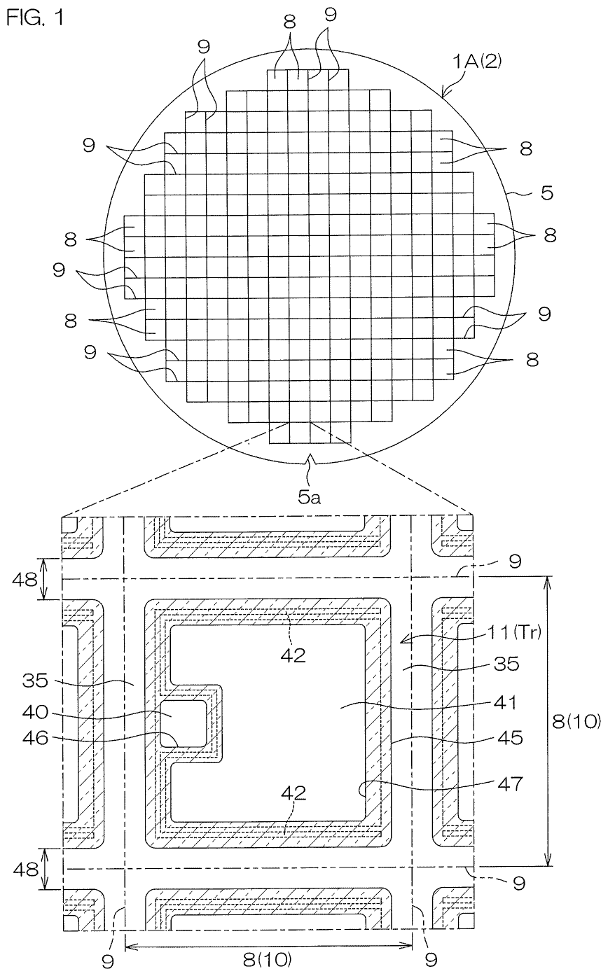

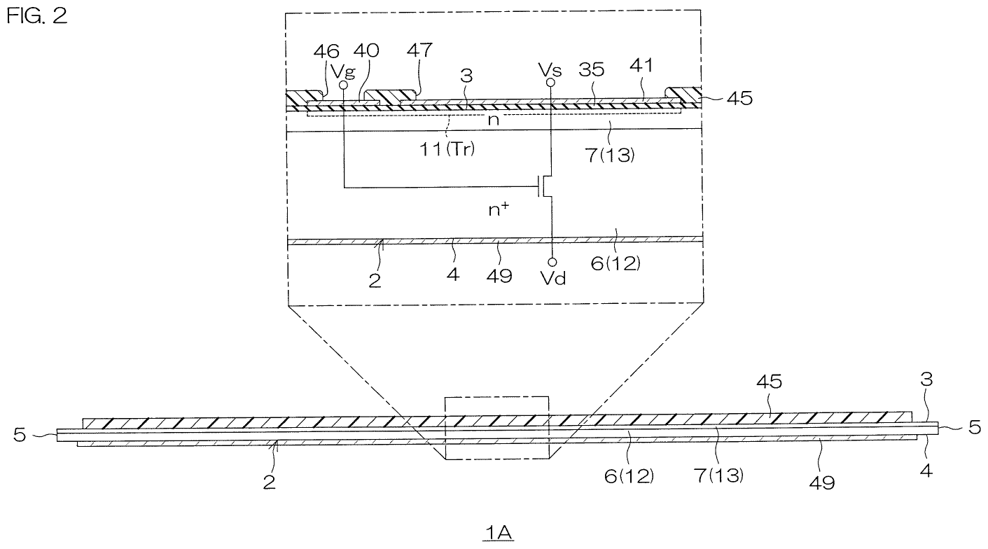

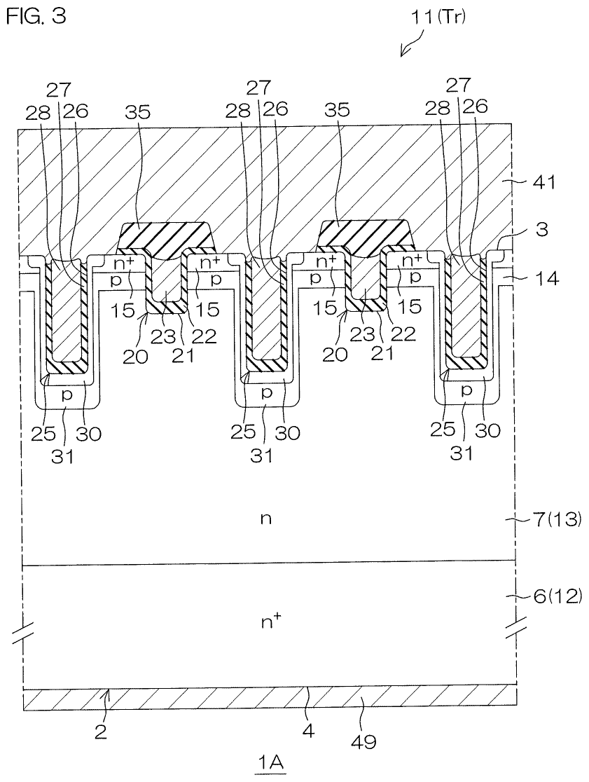

FIG. 1 is a schematic view illustrating a wafer structure 1A according to a first embodiment example. FIG. 2 is a cross-sectional view of the wafer structure 1A illustrated in FIG. 1. FIG. 3 is a cross-sectional view illustrating a principal portion of a device structure 11 of the wafer structure 1A illustrated in FIG. 1. The wafer structure 1A is an intermediate used for manufacturing a semiconductor device 10.

Referring to FIGS. 1 and 2, the wafer structure 1A includes a wafer 2 formed in a flat disk shape. The wafer 2 may be formed in a flat rectangular parallelepiped shape. The wafer 2 includes an SiC single crystal as an example of a wide bandgap semiconductor single crystal. That is, the wafer 2 is formed of an SiC wafer. The wide bandgap semiconductor single crystal is a semiconductor single crystal having a bandgap higher than that of the Si single crystal.

In this embodiment, the wafer 2 is made of hexagonal SiC single crystal and formed in a rectangular parallelepiped shape. The hexagonal SiC single crystal has a plurality of types of polytypes including 2H (hexagonal)-SiC single crystal, 4H-SiC single crystal, 6H-SiC single crystal, and the like. In this embodiment, an example in which the wafer 2 includes the 4H-SiC single crystal is described, but the wafer 2 may include other polytypes.

The wafer 2 has a first surface 3 on one side, a second surface 4 on the other side, and a peripheral end surface 5 connecting the first surface 3 and the second surface 4. The first surface 3 is a device surface, and extends flatly in a horizontal direction. The second surface 4 is a non-device surface and extends flatly in the horizontal direction. That is, the second surface 4 extends substantially parallel to the first surface 3. The peripheral end surface 5 extends in the vertical direction between the first surface 3 and the second surface 4.

The first surface 3 and the second surface 4 are preferably formed of a c-plane of the SiC single crystal. In this case, it is preferable that the first surface 3 is formed of a silicon face ((0001) face) of the SiC single crystal, and the second surface 4 is formed of a carbon face ((000-1) face) of the SiC single crystal.

The wafer 2 (the first surface 3 and the second surface 4) has an off angle inclined at a predetermined angle in a predetermined off direction with respect to the c-plane of the SiC single crystal. That is, the c-axis ((0001)-axis) of the SiC single crystal is inclined by the off angle from the vertical axis in the off direction. Also, the c-plane of the SiC single crystal is inclined by the off angle with respect to the horizontal plane.

The off direction is preferably an a-axis direction ([11-20] direction) of the SiC single crystal. The off angle may exceed 0° and be not more than 10°. The off angle may have a value falling within at least one range of more than 0° and 1° or less, 1° or more and 2.5° or less, 2.5° or more and 5° or less, 5° or more and 7.5° or less, and 7.5° or more and 10° or less.

The off angle is preferably 5° or less. The off angle is particularly preferably 2° or more and 4.5° or less. The off angle is typically set in a range of 4°+0.1°. This specification does not exclude a form in which the off angle is 0° (that is, the first surface 3 is a just surface with respect to the c-plane).

The wafer 2 has a mark 5a indicating the crystal azimuth of the SiC single crystal on the peripheral end surface 5. The mark 5a may indicate either the a-axis direction or an m-axis direction ([1-100] direction). In this embodiment, the mark 5a includes a notched portion. The notched portion may be referred to as an “orientation notch.” The notched portion includes a notched portion recessed in a tapered shape toward a central portion of the first surface 3 along the a-axis direction or the m-axis direction.

The wafer 2 may have a diameter of 2 inches or more and 12 inches or less (50 mm or more and 300 mm or less) in a plan view. The diameter of the wafer 2 is defined by the length (that is, the diameter) of a chord passing through the center of the wafer 2 outside the mark 5a. The diameter of the wafer 2 is preferably 6 inches or more (150 mm or more). The diameter of the wafer 2 is particularly preferably 8 inches or more (200 mm or more).

In this embodiment, the wafer 2 has a layered structure including a first semiconductor layer 6 and a second semiconductor layer 7. The first semiconductor layer 6 is a wafer main body and constitutes a portion of the wafer 2 other than the front surface portion of the first surface 3. The first semiconductor layer 6 is made of the SiC single crystal as an example of a wide bandgap semiconductor single crystal, and has the above-described off direction and off angle. The first semiconductor layer 6 forms the second surface 4 of the wafer 2 and forms a part or a whole of the peripheral end surface 5.

The second semiconductor layer 7 includes an SiC epitaxial layer (SiC semiconductor layer) obtained by crystal-growing the SiC single crystal as an example of a wide bandgap semiconductor single crystal from the first semiconductor layer 6 with the first semiconductor layer 6 as a starting point, and has the above-described off direction and off angle. That is, the wafer 2 is formed of an epitaxial wafer (so-called epi-wafer) in this embodiment.

The wafer structure 1A includes a plurality of device regions 8 and a plurality of planned cutting lines 9 formed in the wafer 2. For example, the plurality of device regions 8 and the plurality of planned cutting lines 9 are demarcated by alignment marks or the like formed in the first surface 3 (second semiconductor layer 7).

The plurality of device regions 8 are regions respectively corresponding to the semiconductor devices 10, and are cut out as the plurality of semiconductor devices 10 in the dicing step. The plurality of device regions 8 are arranged in an orderly manner (for example, in a matrix) along the a-axis direction and the m-axis direction. The plurality of device regions 8 are partitioned in quadrangular shapes in a plan view. The plurality of planned cutting lines 9 extend in a lattice shape along the a-axis direction and the m-axis direction and partition the plurality of device regions 8.

The wafer structure 1A includes a plurality of device structures 11 formed in the plurality of device regions 8 on the first surface 3. Each device structure 11 may include at least one of a switching device, a rectifying device, and a passive device. The switching device may include at least one of a metal insulator semiconductor field effect transistor (MISFET), a bipolar junction transistor (BJT), an insulated gate bipolar junction transistor (IGBT), and a junction field effect transistor (JFET).

The rectifying device may include at least one of a pn junction diode, a pin junction diode, a Zener diode, a Schottky barrier diode, and a fast recovery diode. The passive device may include at least one of a resistor, a capacitor, an inductor, and a fuse.

Each device structure 11 may include a circuit network (e.g., an integrated circuit such as an LSI) in which at least two of a switching device, a rectifying device, and a passive device are combined. In this embodiment, each device structure 11 includes a MISFET structure as an example of a transistor structure Tr. Since structures of the plurality of device regions 8 (device structures 11) are similar, the structure of one device region 8 (device structure 11) will be described below.

FIG. 3 is a cross-sectional view illustrating a principal portion of the device structure 11 related to the wafer structure 1A illustrated in FIG. 1. Referring to FIG. 3, the wafer structure 1A includes an n-type first semiconductor region 12 formed in a region (surface layer portion) on the second surface 4 side inside the wafer 2. A drain potential Vd is to be applied to the first semiconductor region 12. The first semiconductor region 12 may be referred to as a “drain region.”

The first semiconductor region 12 is formed inside the first semiconductor layer 6 and extends in a layer shape along the second surface 4. In this embodiment, the first semiconductor region 12 is formed in the entire region of the first semiconductor layer 6 and is exposed from the second surface 4 and the peripheral end surface 5. In this embodiment, the n-type first semiconductor layer 6 is adopted, and the first semiconductor region 12 is formed by using the n-type first semiconductor layer 6.

The wafer structure 1A includes an n-type second semiconductor region 13 formed in a region (surface layer portion) on the first surface 3 side inside the wafer 2. The second semiconductor region 13 may be referred to as a “drift region.” The second semiconductor region 13 has an n-type impurity concentration lower than the n-type impurity concentration of the first semiconductor region 12.

The second semiconductor region 13 is formed inside the second semiconductor layer 7 and extends in a layer shape along the first surface 3. The second semiconductor region 13 is electrically connected to the first semiconductor region 12 in the layered direction. In this embodiment, the second semiconductor region 13 is formed in the entire region of the second semiconductor layer 7 and is exposed from the first surface 3 and the peripheral end surface 5. In this embodiment, the n-type second semiconductor layer 7 is adopted, and the second semiconductor region 13 is formed using the n-type second semiconductor layer 7.

The wafer structure 1A includes a p-type body region 14 formed in a surface layer portion of the first surface 3. The body region 14 is formed in a surface layer portion of the second semiconductor region 13 (that is, the second semiconductor layer 7). The body region 14 is formed at an interval from the bottom portion of the second semiconductor region 13 toward the first surface 3, and faces the first semiconductor region 12 (that is, the first semiconductor layer 6) with a part of the second semiconductor region 13 interposed therebetween.

The wafer structure 1A includes an n-type source region 15 formed in a surface layer portion of the body region 14. The source region 15 has an n-type impurity concentration higher than that of the second semiconductor region 13. The source region 15 forms a channel having a MISFET structure with the second semiconductor region 13 in the body region 14.

The wafer structure 1A includes a plurality of gate structures 20 of trench electrode type formed at intervals in the first surface 3. A gate potential Vg is to be applied to the gate structure 20. The gate structure 20 may be referred to as a “first structure” or a “trench gate structure.” The plurality of gate structures 20 control channel inversion and non-inversion.

The plurality of gate structures 20 are arranged at intervals in the m-axis direction and extend in a band shape in the a-axis direction. Of course, the plurality of gate structures 20 may be arranged at intervals in the a-axis direction and may extend in a band shape in the m-axis direction. The plurality of gate structures 20 penetrate the body region 14 and the source region 15, and are formed at intervals from the bottom portion of the second semiconductor region 13 toward the first surface 3.

Each gate structure 20 includes a gate trench 21 (first trench), a gate insulating film 22 (first insulating film), and a gate electrode 23 (first electrode). The gate trench 21 is formed in the first surface 3. The gate insulating film 22 covers the wall surface of the gate trench 21. The gate electrode 23 is embedded in the gate trench 21 via the gate insulating film 22.

The wafer structure 1A includes a plurality of source structures 25 of trench electrode type formed in the first surface 3. A source potential Vs is to be applied to the source structure 25. The source structure 25 may be referred to as a “second structure” or a “trench source structure.” Each of the plurality of source structures 25 extends in a band shape in the a-axis direction in a region between two adjacent gate structures 20. As a matter of course, the plurality of source structures 25 may extend in a band shape in the m-axis direction according to the arrangement of the plurality of gate structures 20.

The plurality of source structures 25 penetrate the body region 14 and the source region 15, and are formed at intervals from the bottom portion of the second semiconductor region 13 toward the first surface 3. The plurality of source structures 25 are formed deeper than the plurality of gate structures 20. The plurality of source structures 25 may have a depth that is approximately equal to that of the gate structure 20.

Each source structure 25 includes a source trench 26 (second trench), a source insulating film 27 (second insulating film), and a source electrode 28 (second electrode). The source trench 26 is formed in the first surface 3. The source insulating film 27 covers the wall surface of the source trench 26. The source electrode 28 is embedded in the source trench 26 with the source insulating film 27 interposed therebetween.

The wafer structure 1A includes a plurality of p-type contact regions 30 respectively formed in regions along the plurality of source structures 25 in the second semiconductor region 13. The plurality of contact regions 30 have a p-type impurity concentration higher than the p-type impurity concentration of the body region 14.

The plurality of contact regions 30 are formed in a one-to-many correspondence relationship with respect to the corresponding one source structure 25. The plurality of contact regions 30 are formed at intervals along the corresponding source structure 25 in a plan view. Each contact region 30 extends along the side wall and the bottom wall of the corresponding source structure 25, and is electrically connected to the body region 14 at the surface layer portion of the first surface 3.

The wafer structure 1A includes a plurality of p-type well regions 31 respectively formed in regions along the plurality of source structures 25 in the second semiconductor region 13. Each well region 31 has a p-type impurity concentration higher than the p-type impurity concentration of the body region 14 and lower than the p-type impurity concentration of the contact region 30.

The plurality of well regions 31 are formed in a one-to-one correspondence relationship with respect to the corresponding one source structure 25. The plurality of well regions 31 are formed in a band shape extending along the corresponding one source structure 25 in a plan view. Each well region 31 faces the corresponding source structure 25 with the corresponding plurality of contact regions 30 interposed therebetween. Each well region 31 extends along the side wall and the bottom wall of the corresponding source structure 25, and is electrically connected to the body region 14 at the surface layer portion of the first surface 3.

The wafer structure 1A includes an insulating interlayer film 35 covering the first surface 3. In the entire cross-sectional view illustrated on the lower part of FIG. 2, illustration of the interlayer film 35 is omitted for convenience (hereinafter, the same applies to the corresponding accompanying drawings). The interlayer film 35 may include at least one of a silicon oxide film, a silicon nitride film, and a silicon oxynitride film. The interlayer film 35 is formed over substantially the entire region of the first surface 3. The interlayer film 35 collectively covers the plurality of gate structures 20 in each device region 8.

The wafer structure 1A includes a gate terminal 40, a source terminal 41, and a gate wiring 42. In the overall cross-sectional view illustrated on the lower part of FIG. 2, illustration of the gate terminal 40, the source terminal 41, and the gate wiring 42 is omitted for convenience (hereinafter, the same applies to the corresponding accompanying drawings).

The gate terminal 40 is arranged on the interlayer film 35. The gate terminal 40 is a terminal electrode to which a gate potential Vg is externally applied. The gate terminal 40 may be referred to as a “first terminal electrode,” a “first pad electrode,” a “gate pad electrode,” or the like. The gate terminal 40 is arranged in a region close to a central portion of one side of the device region 8. The gate terminal 40 may be arranged at a corner portion of the device region 8. The gate terminal 40 is formed in a quadrangular shape.

The gate terminal 40 may have a layered structure including a Ti-based metal film and an Al-based metal film. The Ti-based metal film may include one or both of a Ti film and a TiN film. The Al-based metal film may include one or both of an Al film and an Al alloy film. The Al alloy film may include at least one of an AlSi alloy film, an AlCu alloy film, and an AlSiCu alloy film.

The source terminal 41 is arranged on the interlayer film 35 at an interval from the gate terminal 40. The source terminal 41 is a terminal electrode to which the source potential Vs is externally applied. The source terminal 41 may be referred to as a “second terminal electrode,” a “second pad electrode,” a “source pad electrode,” or the like. The source terminal 41 may include the same type of conductive material as the conductive material of the gate terminal 40, and may have a thickness substantially equal to the thickness of the gate terminal 40.

The source terminal 41 is formed in a polygonal shape having a recess portion recessed along the gate terminal 40. The source terminal 41 may be formed in a quadrangular shape. The source terminal 41 is electrically connected to the body region 14, the source region 15, and the plurality of source structures 25 via a plurality of through-holes formed in the interlayer film 35.

The maximum rated gate voltage that can be applied between the gate terminal 40 and the source terminal 41 may be 1 V or more and 100 V or less. The maximum rated gate voltage may have a value belonging to at least one range of 1 V or more and 10 V or less, 10 V or more and 20 V or less, 20 V or more and 30 V or less, 30 V or more and 40 V or less, 40 V or more and 50 V or less, 50 V or more and 60 V or less, 60 V or more and 70 V or less, 70 V or more and 80 V or less, 80 V or more and 90 V or less, and 90 V or more and 100 V or less.

The gate wiring 42 is drawn from the gate terminal 40 onto the interlayer film 35. The gate wiring 42 includes the same type of conductive material as the conductive material of the gate terminal 40, and may have a thickness substantially equal to the thickness of the gate terminal 40. The gate wiring 42 extends in a band shape along the source terminal 41 and surrounds the source terminal 41. The gate wiring 42 intersects (specifically, is orthogonal to) the end portions of the plurality of gate structures 20, and is electrically connected to the plurality of gate structures 20 via a plurality of through-holes formed in the interlayer film 35.

The wafer structure 1A includes an insulating upper insulating film 45 that selectively covers the gate terminal 40 and the source terminal 41 on the interlayer film 35. The upper insulating film 45 covers the entire region of the gate wiring 42. The upper insulating film 45 is preferably thicker than the gate terminal 40 (source terminal 41).

The upper insulating film 45 may include at least one of an inorganic insulating film and an organic insulating film. The upper insulating film 45 may have a single-layer structure including an inorganic insulating film or an organic insulating film. The upper insulating film 45 may have a layered structure including an inorganic insulating film and an organic insulating film layered in this order from the wafer 2 side. The inorganic insulating film may include at least one of a silicon nitride film, a silicon oxynitride film, and a silicon oxide film.

The organic insulating film may include at least one of a photosensitive resin film and a thermosetting resin film. The organic insulating film may have a single-layer structure including a photosensitive resin film. The organic insulating film may have a layered structure including a photosensitive resin film and a thermosetting resin film layered in this order from the wafer 2 side. The photosensitive resin film may be of a negative type or a positive type. The photosensitive resin film may include at least one of a polyimide film, a polyamide film, and a polybenzoxazole film. The thermosetting resin film may include a matrix resin (for example, an epoxy resin) and a plurality of fillers.

The wafer structure 1A includes a gate opening 46, a source opening 47, and a street opening 48 formed in the upper insulating film 45. In the overall cross-sectional view illustrated on the lower part of FIG. 2, illustration of the gate opening 46, the source opening 47, and the street opening 48 is omitted for convenience (hereinafter, the same applies to the corresponding accompanying drawings).

The gate opening 46 exposes an inner portion of the gate terminal 40. The source opening 47 exposes an inner portion of the source terminal 41. The street opening 48 is formed in a lattice shape along the plurality of planned cutting lines 9, and exposes one or both of the first surface 3 and the interlayer film 35.

The wafer structure 1A includes a drain terminal 49 formed on the second surface 4. The drain terminal 49 is a terminal electrode to which a drain potential Vd is externally applied. The drain terminal 49 may be referred to as a “third terminal electrode,” a “third pad electrode,” a “drain pad electrode,” or the like. The drain terminal 49 is electrically connected to the first semiconductor region 12 (first semiconductor layer 6). The drain terminal 49 may include at least one of a Ti film, an Ni film, a Pd film, an Au film, an Ag film, and an Al film.

The maximum rated drain voltage (that is, breakdown voltage) that can be applied between the source terminal 41 and the drain terminal 49 (between the first surface 3 and the second surface 4) may be 500 V or more and 3000 V or less. The maximum rated drain voltage may have a value belonging to at least one range of 500 V or more and 1000 V or less, 1000 V or more and 1500 V or less, 1500 V or more and 2000 V or less, 2000 V or more and 2500 V or less, and 2500 V or more and 3000 V or less.

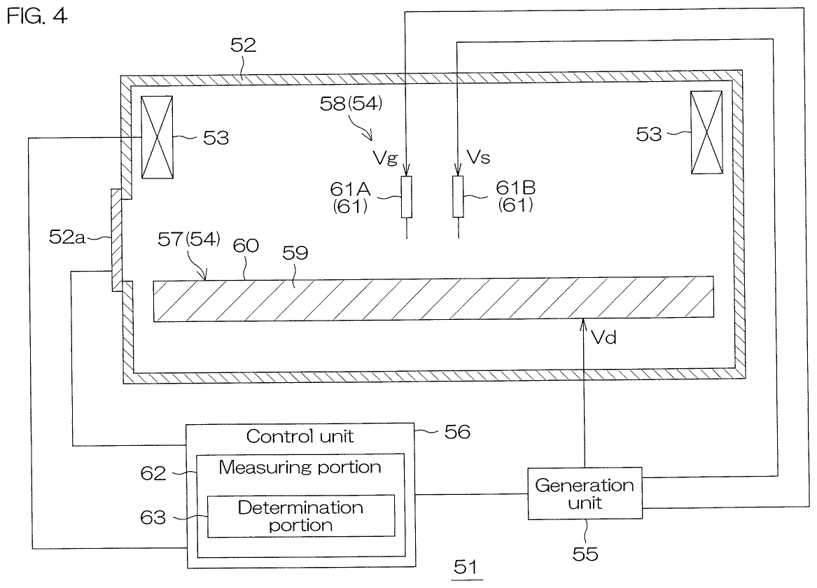

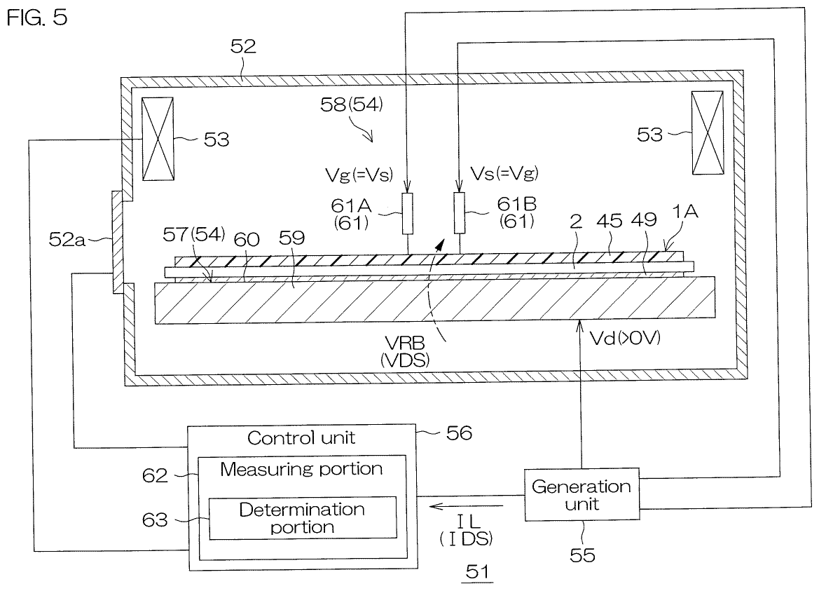

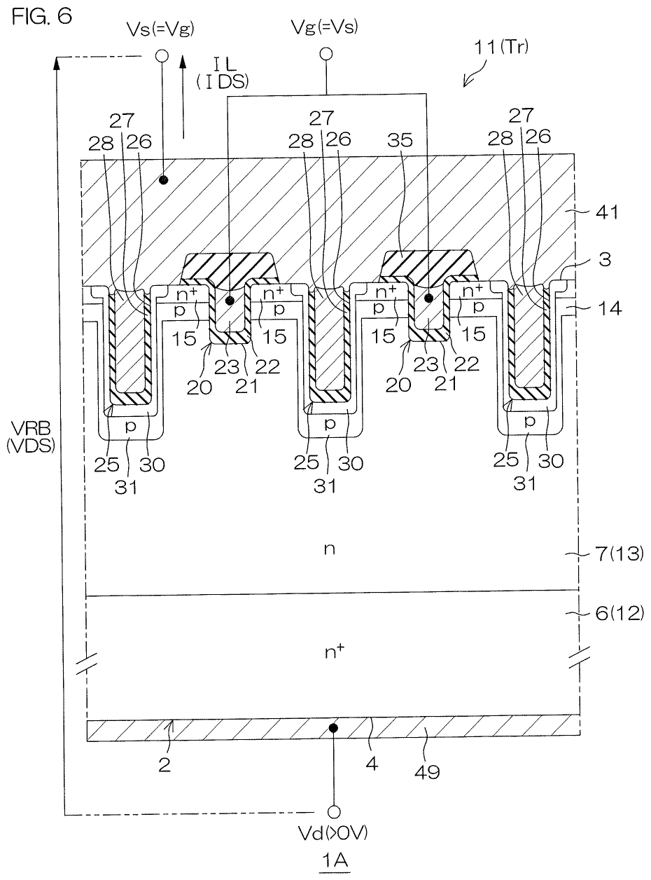

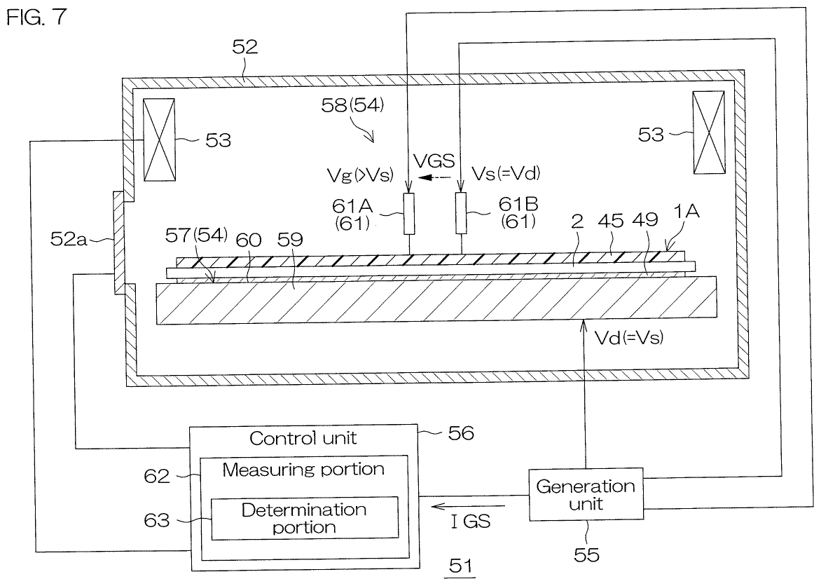

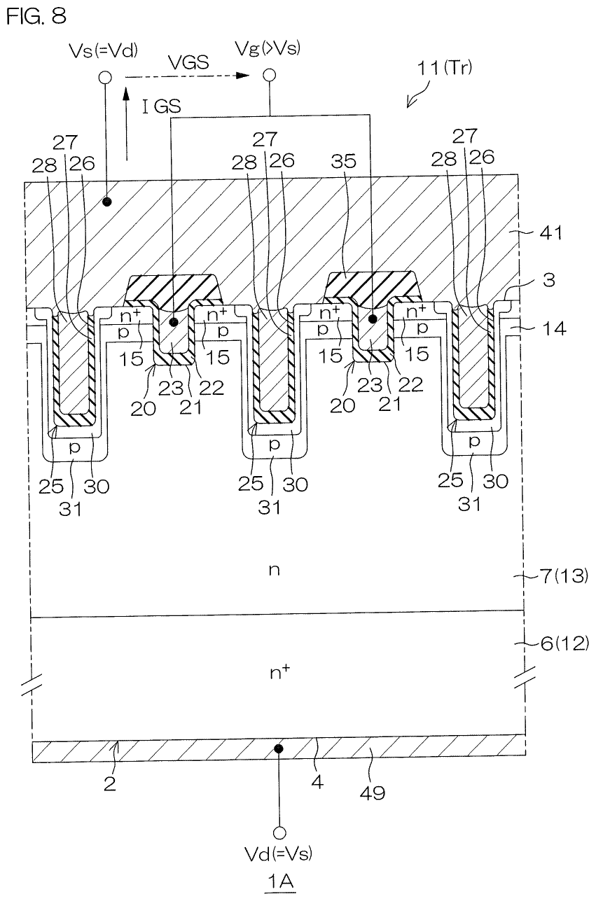

FIG. 4 is a schematic diagram of a semiconductor testing device 51 according to a specific embodiment. FIG. 5 is a schematic diagram illustrating a high temperature reverse bias test related to the semiconductor testing device 51. FIG. 6 is a cross-sectional view illustrating a high temperature reverse bias test together with the device structure 11. FIG. 7 is a schematic diagram illustrating a high temperature gate bias test related to the semiconductor testing device 51. FIG. 8 is a cross-sectional view illustrating a high temperature gate bias test together with the device structure 11.

Referring to FIGS. 4 to 8, the semiconductor testing device 51 is a testing device for performing a high temperature reverse bias test. The high temperature reverse bias test may be referred to as an “HTRB test.” The high temperature reverse bias test is a test in which a reverse bias voltage VRB is to be applied to the device structure 11 under a high temperature environment, and characteristics of a leak current IL are inspected (see FIGS. 5 and 6). The high temperature reverse bias test may be a high temperature/high humidity reverse bias test. In the high temperature/high humidity reverse bias test, the reverse bias voltage VRB is to be applied to the device structure 11 under a high temperature/high humidity environment, and the characteristics of the leak current IL are inspected.

The high temperature reverse bias test may be a total inspection or a sample inspection. In the total inspection, electrical characteristics of all of the plurality of device structures 11 are inspected. The characteristics of the leak current IL of the plurality of device structures 11 may be inspected simultaneously or sequentially. In the sample inspection, electrical characteristics of one or more device structures 11 selected from the plurality of device structures 11 are inspected. The high temperature reverse bias test is preferably a total inspection.

A test period of the high temperature reverse bias test may be 10 hours or more and 3000 hours or less. The test period of the high temperature reverse bias test may be set to a value belonging to at least one range of 10 hours or more and 100 hours or less, 100 hours or more and 500 hours or less, 500 hours or more and 1000 hours or less, 1000 hours or more and 1500 hours or less, 1500 hours or more and 2000 hours or less, 2000 hours or more and 2500 hours or less, and 2500 hours or more and 3000 hours or less.

In addition to the high temperature reverse bias test, the semiconductor testing device 51 may be configured to perform a high temperature gate bias test (see FIGS. 7 and 8). The high temperature gate bias test may be referred to as an “HTGB test.” The high temperature gate bias test is a test in which a gate bias voltage VGS is to be applied to the gate structure 20 under a high temperature environment, and characteristics of a gate leak current IGS are inspected.

The high temperature gate bias test may be a total inspection or sample inspection. In the total inspection, characteristics of all of the plurality of device structures 11 are inspected. The characteristics of the gate leak current IGS of the plurality of device structures 11 may be inspected simultaneously or sequentially. In the sample inspection, characteristics of one or more device structures 11 selected from the plurality of device structures 11 are inspected. The high temperature gate bias test is preferably a total inspection.

A test period of the high temperature gate bias test may be 10 hours or more and 3000 hours or less. The test period of the high temperature gate bias test may be set to a value belonging to at least one range of 10 hours or more and 100 hours or less, 100 hours or more and 500 hours or less, 500 hours or more and 1000 hours or less, 1000 hours or more and 1500 hours or less, 1500 hours or more and 2000 hours or less, 2000 hours or more and 2500 hours or less, and 2500 hours or more and 3000 hours or less.

Referring to FIG. 4, the semiconductor testing device 51 includes a chamber 52, a heating unit 53, a voltage application unit 54, a voltage generation unit 55, and a control unit 56. The chamber 52 includes a box-shaped partition wall that partitions a test space, and includes a transport door 52a through which the wafer structure 1A is carried in and out. The transport door 52a may be an opening/closing shutter.

The heating unit 53 includes a heater arranged within the chamber 52 and increases the temperature within the chamber 52 to a predetermined test temperature. The test temperature may be 50° C. or more and 350° C. or less. The test temperature may have a value belonging to at least one range of 50° C. or more and 75° C. or less, 75° C. or more and 100° C. or less, 100° C. or more and 125° C. or less, 125° C. or more and 150° C. or less, 150° C. or more and 175° C. or less, 175° C. or more and 200° C. or less, 200° C. or more and 225° C. or less, 225° C. or more and 250° C. or less, 250° C. or more and 275° C. or less, 275° C. or more and 300° C. or less, 300° C. or more and 325° C. or less, and 325° C. or more and 350° C. or less. The test temperature is preferably 100° C. or more and 250° C. or less.

The voltage application unit 54 is a unit that applies a predetermined test voltage to the device structure 11 (wafer structure 1A). The voltage application unit 54 includes a stage unit 57 and an application end unit 58.

The stage unit 57 is arranged in the chamber 52. The stage unit 57 includes a plate-shaped (disk-shape in this embodiment) stage terminal 59 as a voltage application end. The stage terminal 59 may be made of metal. The stage terminal 59 has a stage surface 60 to be electrically connected to the second surface 4 (drain terminal 49) of the wafer structure 1A.

The application end unit 58 is arranged in the chamber 52. The application end unit 58 has one or more (in this embodiment, a plurality of) application ends 61 according to the number of terminals of the device structure 11. The application end 61 may be a probe. The type and number of the application ends 61 are appropriately adjusted according to the type and number of terminal electrodes of the device structure 11. The plurality of application ends 61 includes, in this embodiment, a first application end 61A for the gate terminal 40 and a second application end 61B for the source terminal 41.

The application end unit 58 may be configured to simultaneously inspect all of the plurality of device structures 11. In this case, the plurality of first application ends 61A are connected to the gate terminals 40 of all the device structures 11, and the plurality of second application ends 61B are connected to the source terminals 41 of all the device structures 11. As a matter of course, the application end unit 58 may be configured to individually and sequentially inspect the plurality of device structures 11. In this case, one first application end 61A is connected to the gate terminal 40 of one device structure 11, and one second application end 61B is connected to the source terminal 41 of one device structure 11.

The voltage generation unit 55 is a unit that generates a predetermined test voltage and outputs the test voltage to the voltage application unit 54. The voltage generation unit 55 includes a power supply and is electrically connected to the stage unit 57 and the application end unit 58. In this embodiment, the voltage generation unit 55 generates a predetermined drain potential Vd, a predetermined gate potential Vg, and a predetermined source potential Vs, and outputs the drain potential Vd, the gate potential Vg, and the source potential Vs to the stage terminal 59, the first application end 61A, and the second application end 61B, respectively. As a result, the drain potential Vd is applied to the stage terminal 59, the gate potential Vg is applied to the first application end 61A, and the source potential Vs is applied to the second application end 61B.

Referring to FIGS. 5 and 6, the high temperature reverse bias test is performed in a state in which the drain terminal 49 of the wafer structure 1A is electrically connected to the stage terminal 59. The voltage generation unit 55 generates a reverse bias voltage VRB for the device structure 11 in the high temperature reverse bias test. Specifically, the voltage generation unit 55 short-circuits the gate terminal 40 and the source terminal 41, and applies a drain bias voltage VDS as the reverse bias voltage VRB to the drain terminal 49.

That is, the voltage generation unit 55 generates the gate potential Vg, the source potential Vs equal to the gate potential Vg, and the drain potential Vd higher than the source potential Vs. The gate potential Vg and the source potential Vs may be 0 V. The drain bias voltage VDS is a voltage of the drain potential Vd with the source potential Vs as a reference. In the high temperature reverse bias test, a drain cutoff current IDS as the leak current IL is generated between the source terminal 41 and the drain terminal 49 due to the drain bias voltage VDS.

The drain bias voltage VDS may be the maximum rated drain voltage or may be less than the maximum rated drain voltage. A drain voltage ratio of the drain bias voltage VDS to the maximum rated drain voltage may be 0.5 or more and 1 or less. The drain voltage ratio may have a value belonging to at least one range of 0.5 or more and 0.6 or less, 0.6 or more and 0.7 or less, 0.7 or more and 0.8 or less, 0.8 or more and 0.9 or less, and 0.9 or more and 1 or less. The drain voltage ratio is preferably 0.8 or more and 1 or less.

The drain bias voltage VDS may be 500 V or more and 3000 V or less. The drain bias voltage VDS may have a value belonging to at least one range of 500 V or more and 1000 V or less, 1000 V or more and 1500 V or less, 1500 V or more and 2000 V or less, 2000 V or more and 2500 V or less, and 2500 V or more and 3000 V or less.

Referring to FIGS. 7 and 8, the high temperature gate bias test is performed in a state in which the drain terminal 49 of the wafer structure 1A is electrically connected to the stage terminal 59. The voltage generation unit 55 generates a gate bias voltage VGS for the gate terminal 40 (first structure) in the high temperature gate bias test. Specifically, the voltage generation unit 55 short-circuits the source terminal 41 and the drain terminal 49, and applies the gate bias voltage VGS to the gate terminal 40.

That is, the voltage generation unit 55 generates the gate potential Vg, the source potential Vs lower than the gate potential Vg, and the drain potential Vd equal to the source potential Vs. The source potential Vs and the drain potential Vd may be 0 V. The gate bias voltage VGS is a voltage of the gate potential Vg with the source potential Vs as a reference. In the high temperature gate bias test, the gate leak current IGS is generated between the gate terminal 40 and the source terminal 41 due to the gate bias voltage VGS.

The gate bias voltage VGS is adjusted according to a withstand voltage (thickness) of the gate insulating film 22. The gate bias voltage VGS may be the maximum rated gate voltage or may be less than the maximum rated gate voltage. A gate voltage ratio of the gate bias voltage VGS to the maximum rated gate voltage may be 0.5 or more and 1 or less. The gate voltage ratio may have a value belonging to at least one range of 0.5 or more and 0.6 or less, 0.6 or more and 0.7 or less, 0.7 or more and 0.8 or less, 0.8 or more and 0.9 or less, and 0.9 or more and 1 or less. The gate voltage ratio is preferably 0.8 or more and 1 or less.

The gate bias voltage VGS is lower than the drain bias voltage VDS. The gate bias voltage VGS may be 1 V or more and 100 V or less. The gate bias voltage VGS may have a value belonging to at least one range of 1 V or more and 10 V or less, 10 V or more and 20 V or less, 20 V or more and 30 V or less, 30 V or more and 40 V or less, 40 V or more and 50 V or less, 50 V or more and 60 V or less, 60 V or more and 70 V or less, 70 V or more and 80 V or less, 80 V or more and 90 V or less, and 90 V or more and 100 V or less.

The control unit 56 includes a central processing unit, a main storage device, an auxiliary storage device, a communication device, a display device, an input device, and the like, and is connected to the chamber 52, the heating unit 53, the voltage application unit 54, and the voltage generation unit 55. The control unit 56 controls the chamber 52, the heating unit 53, the voltage application unit 54, and the voltage generation unit 55 on the basis of a predetermined processing recipe stored in the auxiliary storage device or the like and performs predetermined processing operations.

The control unit 56 is configured to detect a latent defect of the device structure 11 on the basis of the behavior of the leak current IL (drain cutoff current IDS) of the device structure 11 when the reverse bias voltage VRB (drain bias voltage VDS) is applied. That is, the control unit 56 performs a screening test for checking the presence or absence of the latent defect by using the high temperature reverse bias test. The control unit 56 may be referred to as a “measuring portion,” a “detection unit,” or the like. “Latent defect” according to this specification indicates a potential initial defect that passes through a test method (test item) related to a normal high temperature reverse bias test or a high temperature gate bias test over a long period of time.

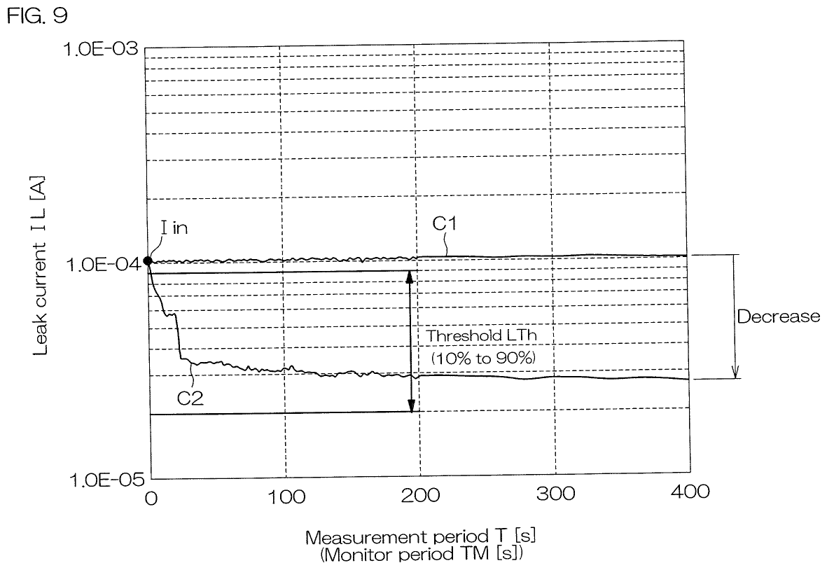

Hereinafter, after an example of the latent defect of the device structure 11 is described, a configuration example of the control unit 56 will be described. FIG. 9 is a graph illustrating initial behavior characteristics of the leak current IL with the time of starting application of the reverse bias voltage VRB as a reference. In FIG. 9, the vertical axis represents the leak current IL [A], and the horizontal axis represents the measurement period T [s] of the leak current IL with the time of starting application of the reverse bias voltage VRB as a reference.

FIG. 9 illustrates the first characteristic C1 and the second characteristic C2 related to the two device structures 11. The first characteristic C1 indicates an initial behavior characteristic of the leak current IL of one device structure 11, and the second characteristic C2 indicates an initial behavior characteristic of the leak current IL of the other device structure 11.

Referring to the first characteristic C1, the leak current IL related to one device structure 11 was substantially constant in the measurement period T. Here, an example of the device structure 11 in which the leak current IL is about 1×10-4 A in the measurement period T is illustrated. In one device structure 11, a variation rate of the leak current IL in the measurement period T was 5% or less.

On the other hand, referring to the second characteristic C2, the leak current IL related to the other device structure 11 greatly decreased in the measurement period T. Specifically, the leak current IL related to the other device structure 11 decreased starting from the start of the test (start of application of the reverse bias voltage VRB). In this example, the leak current IL related to the other device structure 11 sharply decreased immediately after the start of the test and then slowly decreased.

For the second characteristic C2, with an initial value Iin of the leak current IL at the start of the test as a reference, decrease rates of the leak current IL at the time of the lapse of 5 seconds, at the time of the lapse of 10 seconds, at the time of the lapse of 25 seconds, at the time of the lapse of 50 seconds, and at the time of the lapse of 150 seconds were 20% or more, 30% or more, 60% or more, 60% or more, and 70% or more, respectively. Here, an example of the device structure 11 in which the initial value Iin of the leak current IL is about 1×10⁻⁴ A is illustrated. The initial value Iin of the leak current IL takes various values according to a crystal state of the wafer 2, electrical characteristics of the device structure 11, and the like.

Since the leak current IL related to the second characteristic C2 tends to decrease, it was assumed that the other device structure 11 has electrical characteristics superior to the electrical characteristics of the one device structure 11. The researchers of this specification have intensively studied the effect of reducing the leak current IL. As a result, it has been found that the leak current IL related to the first characteristic C1 indicates the initial behavior characteristic of the leak current IL related to the normal device structure 11, and the leak current IL related to the second characteristic C2 indicates the initial behavior characteristic of the leak current IL related to the abnormal device structure 11 having the latent defect.

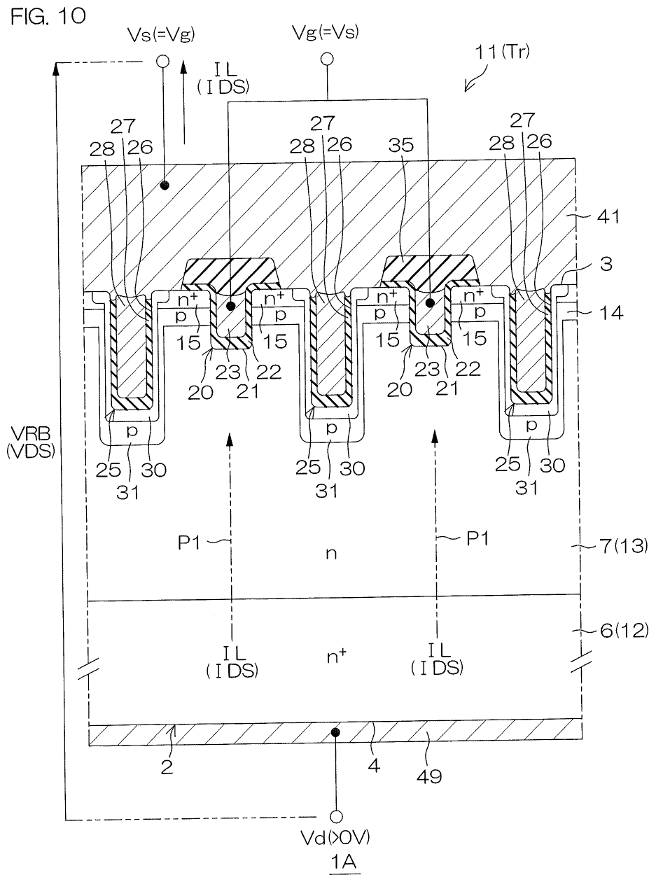

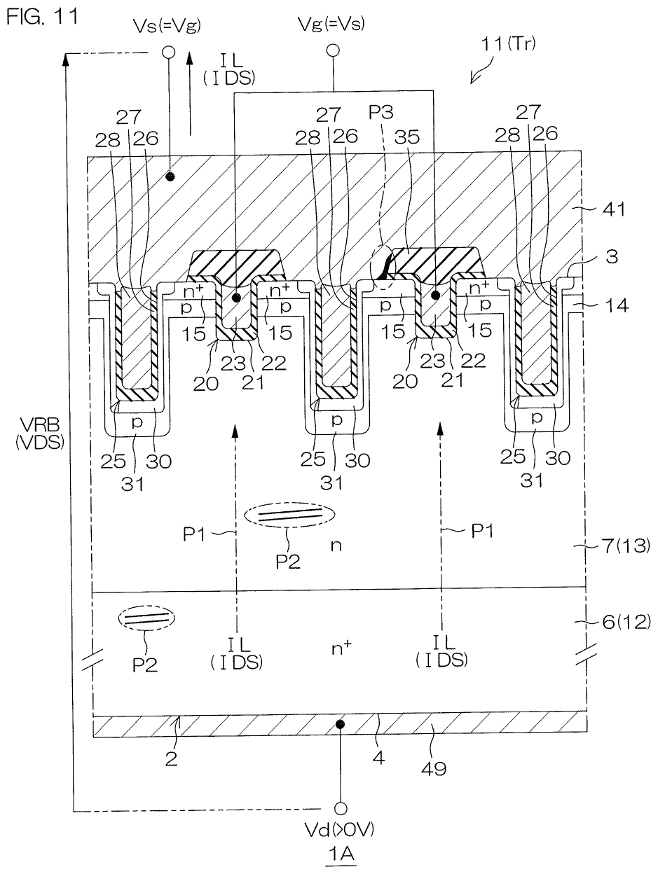

FIG. 10 is a cross-sectional view for describing the normal device structure 11. FIG. 11 is a cross-sectional view for describing the device structure 11 having the latent defect. Referring to FIG. 10, in the case of the normal device structure 11 (first characteristic C1), when the reverse bias voltage VRB is applied to the device structure 11, a first leak path P1 of the leak current IL through the wafer 2 is formed between the source terminal 41 and the drain terminal 49.

The first leak path P1 is considered to be caused by the threading screw dislocation in the SiC single crystal. In the normal device structure 11, since the degree of abnormality of the first leak path P1 (threading screw dislocation) is within the design range, the leak current IL shows no abnormality in behavior.

On the other hand, with reference to FIG. 11, in the device structure 11 (second characteristic C2) having the latent defect, in addition to the first leak path P1, one or both of a second leak path P2 caused by the crystal default of the semiconductor single crystal and a third leak path P3 caused by an undesirable residue or the like generated in the manufacturing process tend to be formed. In the device structure 11 having the latent defect, the second leak path P2 caused by the crystal default tends to be remarkably observed.

The crystal default of the semiconductor single crystal is a stacking default of the semiconductor single crystal formed inside the wafer 2 in many cases, and extends in the lateral direction along the first surface 3 (second surface 4). The stacking default of the semiconductor single crystal may be formed in one or both of the first semiconductor layer 6 and the second semiconductor layer 7. The stacking default of the semiconductor single crystal is a problem related to the manufacturing of the wafer 2, and there is a possibility that the second leak path P2 already exists before the step of forming the device structure 11.

The second leak path P2 may be formed or expanded due to a load (stress or the like) in the step of forming the device structure 11. As a result of the leak current IL flowing through the abnormal first leak path P1, the second leak path P2 may be formed or expanded starting from the first leak path P1. On the other hand, a residue generated in the manufacturing process is generated in the step of forming the device structure 11 or the like, and is attached to the first surface 3 and/or the structure on the first surface 3.

In the device structure 11 having the latent defect, it is considered that the abnormality of the leak current IL occurs due to the abnormality of the first leak path P1, at least one of the second leak path P2 and the third leak path P3, or a combination of at least two of these.

When there is an abnormality exceeding the design range in the first leak path P1 (threading screw dislocation), a part of the leak current IL is consumed as thermal energy in the abnormal portion of the first leak path P1 (threading screw dislocation). When the second leak path P2 (stacking fault) exists, a part of the leak current IL flows into the second leak path P2 (stacking fault) and is consumed as thermal energy. When the third leak path P3 (residue) exists, a part of the leak current IL flows into the third leak path P3 (residue) and is consumed as thermal energy.

As described above, since the device structure 11 having the latent defect has undesirable elements (P1 to P3) that reduce the leak current IL, the leak current IL decreases compared with the normal device structure 11. In the device structure 11 having the latent defect, the leak current IL is reduced at an extremely small decrease rate in the initial stage of the test (initial behavior characteristic). Also, in the device structure 11 having the latent defect, the decrease rate of the leak current IL becomes slow over time, and favorable leak characteristics are observed.

Therefore, the device structure 11 having the latent defect passes through the test item of the normal high temperature reverse bias test and the test item of the high temperature gate bias test, and is distributed on the market as the semiconductor device 10. In the semiconductor device 10 having the latent defect, as a result of load accumulation on the latent defect due to long-term use, a risk of device failure increases.

Referring again to FIG. 4, in this embodiment, the control unit 56 includes a measuring portion 62 configured to detect the latent defect of the device structure 11 on the basis of the behavior (initial behavior characteristics) of the leak current IL. That is, the measuring portion 62 is configured to detect the device structure 11 having one or both of the abnormality of the crystal default and the residue on the basis of the behavior (initial behavior characteristics) of the leak current IL.

The measuring portion 62 is configured to monitor a decrease rate of the leak current IL as a behavior (initial behavior characteristics) of the leak current IL. Specifically, the measuring portion 62 is configured to monitor the decrease rate of the leak current IL of the wafer structure 1A (device structure 11) in the application period of the reverse bias voltage VRB and detect the latent defect of the device structure 11 on the basis of the decrease rate of the leak current IL.

More specifically, the measuring portion 62 has a monitor period TM as a measurement period T with the time of starting application of the reverse bias voltage VRB as a reference, and is configured to monitor the decrease rate of the leak current IL with the initial value Iin of the leak current IL in the monitor period TM as a reference (see FIG. 9).

The initial value Iin of the leak current IL may be any value of the leak current IL measured within 5 seconds from the time of starting application of the reverse bias voltage VRB. The initial value Iin of the leak current IL is preferably set to any value of the leak current IL measured within one second from the time of starting application of the reverse bias voltage VRB. The initial value Iin of the leak current IL may be a value of the leak current IL detected first in the monitor period TM.

Since the decrease rate per unit time of the leak current IL varies depending on an aspect of the latent defect and the specification of the device structure 11, the monitor period TM is adjusted as appropriate depending on the aspect of the latent defect and the specification of the device structure 11. As a matter of course, the monitor period TM may be set on the basis of a statistical value of the decrease time of the leak current IL related to the plurality of device structures 11 having the latent defect.

In the case of the normal high temperature reverse bias test step, since a load is to be applied to the device structure 11 over a long period (for example, several hours to several thousand hours), the measurement period T of the leak current IL is set to a long period (for example, several hours to several thousand hours).

On the other hand, in a case where the device structure 11 has the latent defect, the leak current IL tends to decrease from the time of starting application of the reverse bias voltage VRB due to the latent defect (see FIG. 9). Therefore, the monitor period TM may be set to be shorter than the measurement period T according to the normal high temperature reverse bias test step.

The monitor period TM may be within 60 minutes from the time of starting application of the reverse bias voltage VRB. The monitor period TM may be within 60 minutes, 55 minutes, 50 minutes, 45 minutes, 40 minutes, 35 minutes, 30 minutes, 25 minutes, 20 minutes, 15 minutes, 10 minutes, 5 minutes, or 1 minute. The monitor period TM is preferably within 30 minutes.

For example, when the leak current IL decreases within 100 seconds from the time of starting application of the reverse bias voltage VRB (see the second characteristic C2 in FIG. 9), the monitor period TM may be within 10 minutes, within 5 minutes, or within 1 minute. For example, in the case of the above-described second characteristic C2, the latent defect is detected within 400 seconds.

The measuring portion 62 includes a determination portion 63 that determines the latent defect of the device structure 11 on the basis of the decrease rate of the leak current IL in order to avoid erroneous detection of a normal leak characteristic (first characteristic C1). The determination portion 63 may be configured by software incorporated in the measuring portion 62. The determination portion 63 is configured to determine the latent defect on the basis of a decrease rate of the leak current IL with respect to a reference value set to the leak current IL.

Specifically, the determination portion 63 determines the latent defect on the basis of the decrease rate of the leak current IL with the initial value Iin of the leak current IL in the monitor period TM as a reference. The determination portion 63 may determine that the device structure 11 has the latent defect when the decrease rate of the leak current IL with the initial value Iin of the leak current IL as a reference is 10% or more. The determination portion 63 may determine that there is the latent defect when the decrease rate of the leak current IL is 20% or more.

The determination portion 63 may have a predetermined leak threshold LTh with respect to the decrease rate of the leak current IL with the initial value Iin of the leak current IL as a reference, and determine that the device structure 11 has the latent defect in a case where the decrease rate of the leak current IL exceeds the leak threshold LTh. The leak threshold LTh may be 10% or more and 90% or less.

The leak threshold LTh may have a value belonging to at least one range of 10% or more and 15% or less, 15% or more and 20% or less, 20% or more and 25% or less, 25% or more and 30% or less, 30% or more and 35% or less, 35% or more and 40% or less, 40% or more and 45% or less, 45% or more and 50% or less, 50% or more and 55% or less, 55% or more and 60% or less, 60% or more and 65% or less, 65% or more and 70% or less, 70% or more and 75% or less, 75% or more and 80% or less, 80% or more and 85% or less, and 85% or more and 90% or less. The leak threshold LTh is preferably 10% or more. The leak threshold LTh is particularly preferably 20% or more. The leak threshold LTh may be 60% or less. The leak threshold LTh may be 50% or less.

The determination portion 63 may determine that the device structure 11 has the latent defect when the decrease rate of the leak current IL becomes equal to or greater than the leak threshold LTh within the monitor period TM. For example, in a case where the leak threshold LTh is set to 20%, the device structure 11 having the second characteristic C2 is determined to have the latent defect after 5 seconds (see FIG. 9). For example, in a case where the leak threshold LTh is set to 30%, the device structure 11 having the second characteristic C2 is determined to have the latent defect after 10 seconds (see FIG. 9).

As a matter of course, the determination portion 63 may determine that the device structure 11 has the latent defect in a case where the decrease rate of the leak current IL at the end of the monitor period TM is the leak threshold LTh or more. For example, in a case where the leak threshold LTh is set to a value in a range of 20% or more and 70% or less, the device structure 11 having the second characteristic C2 is determined to have the latent defect at the end of the monitor period TM (see FIG. 9).

The control unit 56 may be configured to store the determination result for the device structure 11 after the latent defect determination in an auxiliary storage device or the like, and exclude the device structure 11 having the latent defect from the manufacturing line in the subsequent manufacturing process. In this case, the determination result of the latent defect related to one or more (preferably all) device structures 11 may be stored in the auxiliary storage device or the like in association with an identification number of the device structure 11 or a map of the wafer 2.

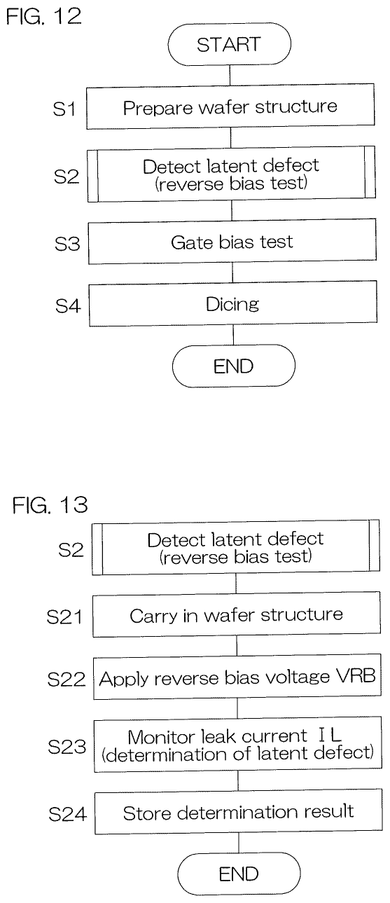

FIG. 12 is a step diagram illustrating an example of a method of manufacturing the semiconductor device 10 according to a specific embodiment. Hereinafter, FIGS. 1 to 11 will be appropriately referred to, as necessary. In the following description, matters overlapping with the matters described for the semiconductor testing device 51 will be omitted as appropriate.

The method of manufacturing the semiconductor device 10 includes a step (S1) of preparing the above-described wafer structure 1A (see FIGS. 1 to 3). The method of manufacturing the semiconductor device 10 includes a step (S2) of detecting the latent defect of the device structure 11. The latent defect detection step (S2) is performed by using the above-described semiconductor testing device 51 (see FIG. 4). The latent defect detection step (S2) may be incorporated into a normal high temperature reverse bias test step. In this case, the monitor period TM can be set at the beginning of the measurement period T of the normal high temperature reverse bias test (that is, at the time of starting the test).

The latent defect detection step (S2) may be performed separately from a normal high temperature reverse bias test step. The latent defect detection step (S2) may be performed before the normal high temperature reverse bias test. The latent defect detection step (S2) may be performed after the normal high temperature reverse bias test. In view of characteristic variations of the leak current IL due to the normal high temperature reverse bias test, the latent defect detection step (S2) is preferably performed before the normal high temperature reverse bias test.

Hereinafter, the latent defect detection step (S2) will be described with reference to FIG. 13. FIG. 13 is a step diagram illustrating an example of the latent defect detection step (S2). Referring to FIG. 13, the detection step (S2) includes a step (S21) of carrying the wafer structure 1A into the above-described semiconductor testing device 51 (see FIG. 4). The wafer structure 1A is arranged on the stage terminal 59 in a posture in which the drain terminal 49 faces the stage surface 60. Thus, the drain terminal 49 is electrically connected to the stage terminal 59 (see also FIG. 5).

The detection step (S2) includes a step (S22) of applying the reverse bias voltage VRB to the device structure 11 after the step (S21) of carrying in the wafer 2. In the application step (S22), the gate terminal 40 and the source terminal 41 are short-circuited under a predetermined test temperature, and the drain bias voltage VDS as the reverse bias voltage VRB is applied to the drain terminal 49 (see also FIGS. 5 and 6). As a result, the drain cutoff current IDS as the leak current IL is generated between the source terminal 41 and the drain terminal 49.

The detection step (S2) includes a step (S23) of monitoring a behavior of the leak current IL. The step (S23) of monitoring the leak current IL includes a step of monitoring a decrease rate of the leak current IL. Specifically, the monitor step (S23) includes a step of monitoring the decrease rate of the leak current IL with respect to the initial value Iin of the leak current IL in a predetermined monitor period TM with the time of starting application of the reverse bias voltage VRB as a reference.

The monitor step (S23) includes a step (S23) of determining the latent defect of the device structure 11. In the latent defect determination step (S23), the latent defect of the device structure 11 is determined on the basis of the decrease rate of the leak current IL in order to avoid erroneous detection of the normal device structure 11. Specifically, in the determination step (S23), the latent defect is determined on the basis of the decrease rate of the leak current IL with the initial value Iin of the leak current IL in the monitor period TM as a reference.

The determination step (S23) may include a step of determining that the device structure 11 has the latent defect in a case where the decrease rate of the leak current IL with the initial value Iin of the leak current IL as a reference is 10% or more. The latent defect determination step (S23) may include a step of determining that the device structure 11 has the latent defect in a case where the decrease rate of the leak current IL is 20% or more.

The latent defect determination step (S23) may include a step of, when the above-described leak threshold LTh (for example, 10% or more and 90% or less) is provided for the decrease rate of the leak current IL with the initial value Iin of the leak current IL as a reference, determining that the device structure 11 has the latent defect in a case where the decrease rate of the leak current IL exceeds the leak threshold LTh.

The latent defect detection step (S2) includes a step (S24) of storing the determination result in an auxiliary storage device or the like. In the storage step (S24), the determination result of the latent defect related to one or more (preferably all) device structures 11 is stored in the auxiliary storage device or the like in association with an identification number of the device structure 11 or a map of the wafer 2. Thus, the device structure 11 having the latent defect will be excluded from the manufacturing line in the subsequent steps.

Referring to FIG. 12 again, the method of manufacturing the semiconductor device 10 includes a high temperature gate bias test (S3). The high temperature gate bias test (S3) is preferably performed after the latent defect detection step (S2). As a matter of course, the high temperature gate bias test (S3) may be performed before the latent defect detection step (S2).

In the high temperature gate bias test (S3), the source terminal 41 and the drain terminal 49 are short-circuited under a predetermined test temperature, and the gate bias voltage VGS is applied to the gate structure 20 (see also FIGS. 7 and 8). As a result, the gate leak current IGS is generated between the gate terminal 40 and the source terminal 41 and monitored. After the high temperature gate bias test (S3), the wafer structure 1A is carried out of the semiconductor testing device 51.

The method of manufacturing the semiconductor device 10 includes a step (S4) of dicing the wafer structure 1A after the high temperature reverse bias test (S2) and the high temperature gate bias test (S3). In the dicing step (S4), the wafer structure 1A is cut along the planned cutting lines 9, and a plurality of device regions 8 (device structures 11) are respectively cut out as a plurality of semiconductor devices 10. The semiconductor devices 10 are manufactured through steps including the above steps.

As described above, in the specific embodiment, the method of manufacturing the semiconductor device 10 including the reverse bias test (S2) for the device structure 11 is provided. The reverse bias test (S2) includes the step of applying the reverse bias voltage VRB (S22) and the step of monitoring the leak current IL (S23). In the application step (S22), the reverse bias voltage VRB is applied to the device structure 11. In the monitor step (S23), the decrease rate of the leak current IL of the device structure 11 is monitored at the time of applying the reverse bias voltage VRB.

According to this manufacturing method, it is possible to detect the device structure 11 having the latent defect on the basis of the decrease rate of the leak current IL. For example, the monitor step (S23) may include the step of determining the latent defect of the device structure 11 on the basis of the decrease rate of the leak current IL. As a result, the device structure 11 having the latent defect is excluded from the manufacturing line, and the distribution of the semiconductor device 10 having the latent defect to the market is suppressed.

The monitor step (S23) preferably includes the step of determining the latent defect of the device structure 11 on the basis of the decrease rate of the leak current IL with the initial value Iin of the leak current IL as a reference. The leak current IL of the device structure 11 having the latent defect has a characteristic of decreasing from the time of starting application of the reverse bias voltage VRB (see the second characteristic C2 in FIG. 9). Therefore, by using the initial value Iin of the leak current IL as a reference, erroneous detection of the normal device structure 11 is suppressed, and the device structure 11 having the latent defect is appropriately detected.

The monitor step (S23) preferably includes the step of determining that the device structure 11 has the latent defect in a case where the decrease rate of the leak current IL is 10% or more. The monitor step (S23) preferably includes the step of determining that the device structure 11 has the latent defect in a case where the decrease rate of the leak current IL is 20% or more. According to the manufacturing method, erroneous detection of the normal device structure 11 is appropriately suppressed.

The monitor step (S23) may include the step of monitoring the decrease rate of the leak current IL from the start of the application of the reverse bias voltage VRB. That is, the monitor step (S23) may include the step of monitoring the decrease rate of the initial behavior of the leak current IL. The monitor step (S23) may include the step of monitoring the decrease rate of the leak current IL in the monitor period TM with the time of starting application of the reverse bias voltage VRB as a reference.

The leak current IL of the device structure 11 having the latent defect has a characteristic of decreasing from the time of starting application of the reverse bias voltage VRB (see the second characteristic C2 in FIG. 9). Therefore, by setting the monitor period TM with the time of starting application of the reverse bias voltage VRB as a reference, erroneous detection of the normal device structure 11 is suppressed, and the device structure 11 having the latent defect is appropriately detected.

Since the leak current IL of the device structure 11 having the latent defect has a characteristic of decreasing from the time of starting application of the reverse bias voltage VRB (see the second characteristic C2 in FIG. 9), the latent defect is detected in a relatively short period. For example, the monitor period TM in the monitor step (S23) may be set shorter than the test time of the normal high temperature reverse bias test or the test time of the normal high temperature gate bias test. For example, the monitor period TM may be within 60 minutes. For example, the monitor period TM may be within 30 minutes.

The reverse bias test (S2) may be the high temperature reverse bias test (S2) in which the reverse bias voltage VRB is applied under a high temperature environment. The monitor step (S23) may be performed in a relatively short period, and may thus be incorporated into a normal high temperature reverse bias test. For example, the monitor step (S23) may be incorporated at the time of starting a normal high temperature reverse bias test.

The reverse bias voltage VRB may be 500 V or more and 3000 V or less. The reverse bias test (S2) is preferably the wafer-level test for the device structures 11 formed on the wafer 2. According to this manufacturing method, since the latent defect of the device structure 11 is detected at the wafer level before the dicing step (S3), a packaging step for the semiconductor device 10 having the latent defect is not required after the dicing step (S3). This reduces manufacturing costs.

The wafer 2 preferably includes the SiC single crystal as an example of the wide bandgap semiconductor single crystal. According to this manufacturing method, the semiconductor device 10 as an SiC semiconductor device is manufactured. In the case of an SiC semiconductor device, due to the physical properties (electrical characteristics) of the SiC single crystal, the SiC semiconductor device is used under a high load environment (under a high voltage and/or high temperature environment). For example, the SiC semiconductor device can be mounted on a drive source of a motor of a hybrid vehicle, an electric vehicle, a fuel cell vehicle, or the like.

In a case where an SiC semiconductor device having the latent defect is used under a high load environment, the risk of device failure starting from the latent defect portion increases. In this regard, according to the method of manufacturing the semiconductor device 10, the latent defect of the device structure 11 as the SiC semiconductor device can be detected. Therefore, distribution of the SiC semiconductor device having the latent defect to the market is suppressed. As a result, a reduction in reliability of the application caused by the SiC semiconductor device having the latent defect is suppressed.

The device structure 11 may include the transistor structure Tr. According to this manufacturing method, the latent defect of the device structure 11 including the transistor structure Tr can be detected. The transistor structure Tr may have the gate, the source, and the drain. In this case, the reverse bias voltage VRB is the drain bias voltage VDS, and the leak current IL is the drain cutoff current IDS. The method of manufacturing the semiconductor device 10 may include the gate bias test (S3) for the transistor structure Tr.

From another viewpoint, in the specific embodiment, there is provided the semiconductor testing device 51 that performs the reverse bias test (S2) on the device structure 11. The semiconductor testing device 51 includes the voltage application unit 54, the voltage generation unit 55, and the control unit 56. The voltage application unit 54 applies the test voltage to the device structure 11. The voltage generation unit 55 generates the reverse bias voltage VRB as the test voltage and outputs the reverse bias voltage VRB to the voltage application unit 54. The control unit 56 monitors the decrease rate of the leak current IL of the device structure 11 at the time of applying the reverse bias voltage VRB.

According to the semiconductor testing device 51, it is possible to detect the device structure 11 having the latent defect on the basis of the decrease rate of the leak current IL. For example, the control unit 56 can determine the latent defect of the device structure 11 on the basis of the decrease rate of the leak current IL. As a result, the device structure 11 having the latent defect is excluded from the manufacturing line, and the distribution of the semiconductor device 10 having the latent defect to the market is suppressed.

The control unit 56 preferably determines the latent defect of the device structure 11 on the basis of the decrease rate of the leak current IL with the initial value Iin of the leak current IL as a reference. According to this configuration, erroneous detection of the normal device structure 11 is suppressed, and the device structure 11 having the latent defect is appropriately detected.

The control unit 56 preferably determines that the device structure 11 has the latent defect in a case where the decrease rate of the leak current IL is 10% or more. The control unit 56 preferably determines that the device structure 11 has the latent defect in a case where the decrease rate of the leak current IL is 20% or more. According to these configurations, erroneous detection of the normal device structure 11 is appropriately suppressed.

The control unit 56 preferably monitors the decrease rate of the leak current IL in the monitor period TM with the time of starting application of the reverse bias voltage VRB as a reference. According to this configuration, erroneous detection of the normal device structure 11 is suppressed, and the device structure 11 having the latent defect is appropriately detected. For example, the monitor period TM may be within 60 minutes. For example, the monitor period TM may be within 30 minutes.

The reverse bias test (S2) may be the high temperature reverse bias test (S2). The reverse bias voltage VRB may be 500 V or more and 3000 V or less. The reverse bias test (S2) is preferably the wafer-level test for the device structures 11 formed on the wafer 2.

According to the semiconductor testing device 51, since the latent defect of the device structure 11 is detected at the wafer level before the dicing step (S3), a packaging step for the semiconductor device 10 having the latent defect is not required after the dicing step (S3). This reduces manufacturing costs.

The wafer 2 preferably includes the SiC single crystal as an example of the wide bandgap semiconductor single crystal. According to the semiconductor testing device 51, the latent defect of the device structure 11 as an SiC semiconductor device can be detected. Therefore, according to the semiconductor testing device 51, the distribution of an SiC semiconductor device having the latent defect to the market is suppressed, and a reduction in the reliability of applications caused by the SiC semiconductor device having the latent defect is suppressed. The semiconductor testing device 51 may be a device that performs the reverse bias test (S2) on the device structure 11 according to the in-vehicle semiconductor device 10 (SiC semiconductor device).

The device structure 11 may include the transistor structure Tr. According to the semiconductor testing device 51, the latent defect of the device structure 11 including the transistor structure Tr can be detected. The transistor structure Tr may have the gate, the source, and the drain. In this case, the reverse bias voltage VRB is the drain bias voltage VDS, and the leak current IL is the drain cutoff current IDS. The semiconductor testing device 51 may be configured to perform the gate bias test (S3) on the transistor structure Tr.

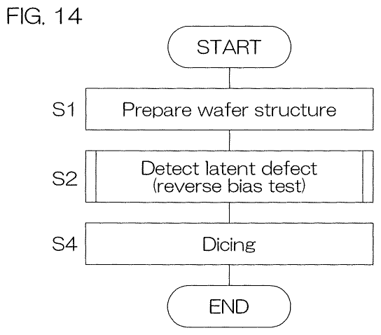

FIG. 14 is a step diagram illustrating another example of the method of manufacturing the semiconductor device 10 according to the specific embodiment. In the method of manufacturing the semiconductor device 10 according to another example, the latent defect detection step (S2) as the high temperature reverse bias test is performed, while the high temperature gate bias test (S3) is omitted. In the high temperature gate bias test (S3), the gate bias voltage VGS lower than the drain bias voltage VDS related to the latent defect detection step (S2) is applied to the gate structure 20.

Thus, a load to be applied to the gate structure 20 due to the gate bias voltage VGS can be smaller than a load to be applied to the gate structure 20 due to the drain bias voltage VDS. Therefore, in a case where the reliability of the gate structure 20 is secured in the latent defect detection step (S2), the method of manufacturing the semiconductor device 10 according to another example may be adopted. As a matter of course, the latent defect detection step (S2) may be incorporated into a normal high temperature reverse bias test.

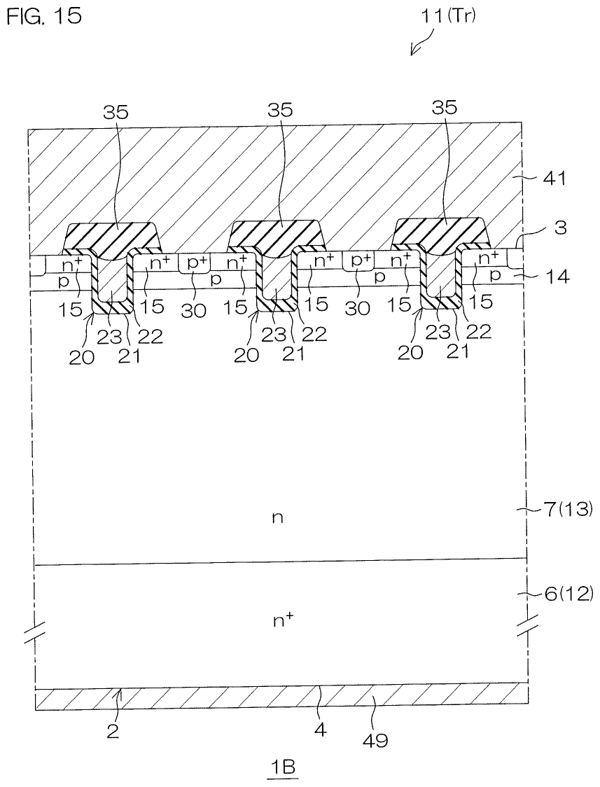

Hereinafter, another embodiment example of the wafer structure 1A will be described. FIG. 15 is a cross-sectional view illustrating a principal portion of the device structure 11 of a wafer structure 1B according to a second embodiment example. Referring to FIG. 15, the wafer structure 1B according to the second embodiment example does not have the source structure 25 in the device structure 11.

In this embodiment, the above-described contact region 30 is formed in the surface layer portion of the body region 14 in the region between the two adjacent gate structures 20. In this embodiment, the above-described source terminal 41 is electrically connected to the body region 14, the source region 15, and the plurality of contact regions 30 via a plurality of through-holes formed in the interlayer film 35.

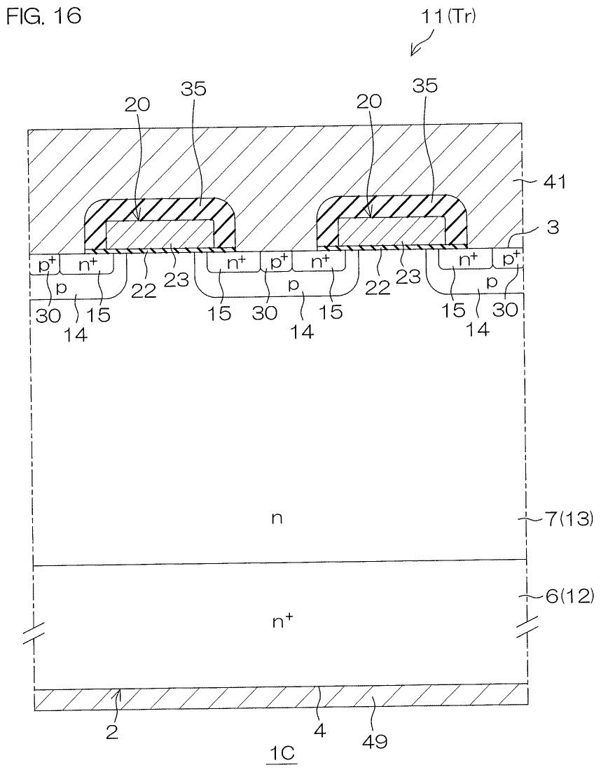

FIG. 16 is a cross-sectional view illustrating a principal portion of the device structure 11 of a wafer structure 1C according to a third embodiment example. Referring to FIG. 16, the wafer structure 1C according to the third embodiment example has a planar electrode type gate structure 20 instead of the trench electrode type gate structure 20 in the device structure 11. The gate structures 20 may be referred to as a “planar gate structure.” Since structures of the plurality of device structures 11 are similar, a structure of one device structure 11 will be described below.

The wafer structure 1C includes a plurality of p-type body regions 14 formed at intervals in the surface layer portion of the first surface 3. The plurality of body regions 14 are formed in the surface layer portion of the second semiconductor region 13 (that is, the second semiconductor layer 7). The plurality of body regions 14 are formed at intervals from the bottom portion of the second semiconductor region 13 toward the first surface 3, and face the first semiconductor region 12 (that is, the first semiconductor layer 6) with a part of the second semiconductor region 13 interposed therebetween.

The wafer structure 1C includes a plurality of n-type source regions 15 respectively formed in the surface layer portions of the plurality of body regions 14. The plurality of source regions 15 are formed at intervals in the surface layer portion of the corresponding body region 14. Each of the plurality of source regions 15 forms a channel having a MISFET structure with the second semiconductor region 13 in the surface layer portion of the corresponding body region 14.

The wafer structure 1C includes a plurality of n-type contact regions 30 respectively formed in the surface layer portions of the plurality of body regions 14. The plurality of contact regions 30 are formed in a region between the plurality of adjacent source regions 15 in the surface layer portion of the corresponding body region 14.

The wafer structure 1C includes a plurality of gate structures 20 of a planar electrode type arranged at intervals on the first surface 3. The plurality of gate structures 20 are arranged across two adjacent body regions 14, and cover the plurality of source regions 15 located in one and the other body regions 14.

Each gate structure 20 has a layered structure including the gate insulating film 22 and the gate electrode 23. The gate insulating film 22 is arranged across the two adjacent body regions 14, and covers the plurality of source regions 15 located in one and the other body regions 14. The gate electrode 23 is arranged on the gate insulating film 22 across the two adjacent body regions 14, and covers the plurality of source regions 15 located in one and the other body regions 14 with the gate insulating film 22 interposed therebetween. The gate electrode 23 faces the plurality of channels with the gate insulating film 22 interposed therebetween.

Similarly to the wafer structure 1A according to the first embodiment example, the wafer structure 1C includes the interlayer film 35, the gate terminal 40, the source terminal 41, the gate wiring 42, the upper insulating film 45, and the drain terminal 49. In this embodiment, the source terminal 41 is electrically connected to the plurality of body regions 14, the plurality of source regions 15, and the plurality of contact regions 30 via a plurality of through-holes formed in the interlayer film 35.

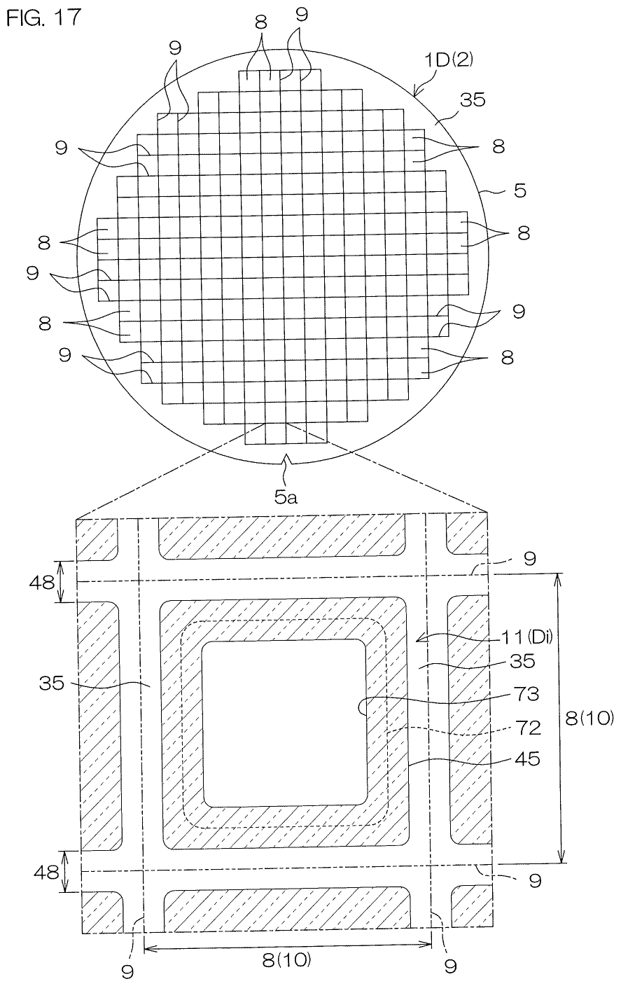

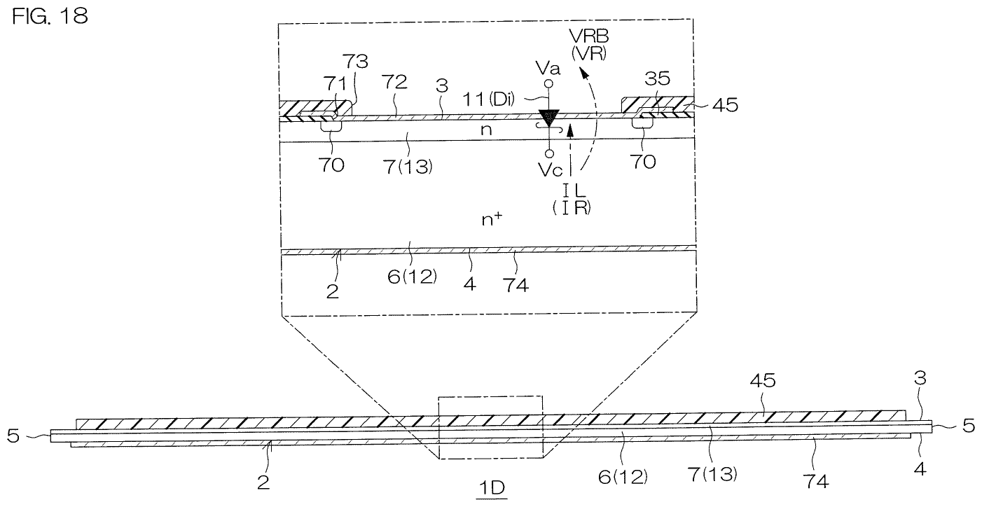

FIG. 17 is a cross-sectional view illustrating a principal portion of the device structure 11 of a wafer structure 1D according to a fourth embodiment example. FIG. 18 is a cross-sectional view of the wafer structure 1D illustrated in FIG. 17. The wafer structure 1A described above has the transistor structure Tr as an example of the device structure 11. On the other hand, the wafer structure 1D according to the fourth embodiment example has a diode structure Di as an example of the device structure 11. The above-described first semiconductor region 12 is formed as a “cathode region” in this embodiment. Since structures of the plurality of device structures 11 are similar, a structure of one device structure 11 will be described below.

The wafer structure 1D includes a p-type impurity region 70 formed in the surface layer portion of the first surface 3. The impurity region 70 is formed in the surface layer portion of the second semiconductor region 13. The impurity region 70 is formed in a polygonal annular shape (a square annular shape in this embodiment) surrounding the inner portion of the device region 8 in a plan view. The impurity region 70 is formed at an interval from the bottom portion of the second semiconductor region 13 toward the first surface 3, and faces the first semiconductor region 12 with a part of the second semiconductor region 13 interposed therebetween.

The wafer structure 1D includes the interlayer film 35 that selectively covers the first surface 3 as in the case of the wafer structure 1A according to the first embodiment example. The interlayer film 35 is formed over substantially the entire region of the first surface 3 and has an opening 71 for selectively exposing the first surface 3. In this embodiment, the opening 71 has an opening wall surface located on the impurity region 70, and exposes the inner edge portions of the second semiconductor region 13 and the impurity region 70. The opening 71 is formed in a polygonal shape (quadrangular shape in this embodiment) extending along the impurity region 70 in a plan view, and exposes the inner peripheral portion of the impurity region 70 over the entire periphery.

The wafer structure 1D includes an anode terminal 72 arranged on the first surface 3. The anode terminal 72 is a terminal electrode to which the anode potential Va is externally applied. The anode terminal 72 may be referred to as a “first terminal electrode,” a “first pad electrode,” an “anode pad electrode,” or the like. The anode terminal 72 is formed in a polygonal shape (quadrangular shape in this embodiment) along the peripheral edge of the device region 8 in a plan view.

The anode terminal 72 enters the opening 71 from above the interlayer film 35, and is electrically connected to the inner edge portions of the second semiconductor region 13 and the impurity region 70. The anode terminal 72 forms a Schottky junction with the second semiconductor region 13. As a result, a Schottky barrier diode structure as an example of the diode structure Di is formed in the device region 8. The Schottky barrier diode structure has the anode terminal 72 as an anode and the second semiconductor region 13 (first semiconductor region 12) as a cathode.

The wafer structure 1D includes the upper insulating film 45 covering the first surface 3 as in the case of the wafer structure 1A according to the first embodiment example. The upper insulating film 45 is formed on the interlayer film 35 and covers the first surface 3 via the interlayer film 35. The upper insulating film 45 selectively covers the anode terminal 72 on the interlayer film 35. The upper insulating film 45 is preferably thicker than the anode terminal 72.

The wafer structure 1A includes an anode opening 73 and the street opening 48 formed in the upper insulating film 45. The anode opening 73 exposes an inner portion of the anode terminal 72. The street opening 48 is formed in the lattice shape along the plurality of planned cutting lines 9, and exposes one or both of the first surface 3 and the interlayer film 35.

The wafer structure 1A includes a cathode terminal 74 formed on the second surface 4. The cathode terminal 74 is a terminal electrode to which the cathode potential Vc is externally applied. The cathode terminal 74 may be referred to as a “second terminal electrode,” a “second pad electrode,” a “cathode pad electrode,” or the like. The cathode terminal 74 is electrically connected to the first semiconductor region 12 (first semiconductor layer 6). The cathode terminal 74 may include at least one of a Ti film, an Ni film, a Pd film, an Au film, an Ag film, and an Al film.

The maximum rated reverse voltage (that is, breakdown voltage) that can be applied between the anode terminal 72 and the cathode terminal 74 (between the first surface 3 and the second surface 4) may be 500 V or more and 3000 V or less. The maximum rated drain voltage may have a value belonging to at least one range of 500 V or more and 1000 V or less, 1000 V or more and 1500 V or less, 1500 V or more and 2000 V or less, 2000 V or more and 2500 V or less, and 2500 V or more and 3000 V or less.

In a case where the wafer structure 1D is adopted, the above-described latent defect detection step (high temperature reverse bias test) (S2) is performed, but the high temperature gate bias test (S3) is not performed. In a case where the wafer structure 1D is adopted, the semiconductor testing device 51 is configured to apply the reverse bias voltage VRB to the diode structure Di. Specifically, the application end unit 58 related to the voltage application unit 54 includes an application end 61 for the anode terminal 72.

On the other hand, the voltage generation unit 55 generates a predetermined anode potential Va and a predetermined cathode potential Vc, and outputs the anode potential Va and the cathode potential Vc to the stage terminal 59 and the application end 61, respectively. The voltage generation unit 55 generates the reverse bias voltage VRB for the diode structure Di in the latent defect detection step (S2).

Specifically, the voltage generation unit 55 generates the anode potential Va and the cathode potential Vc higher than the anode potential Va, and applies the cathode potential Vc to the stage unit 57 and the application end unit 58. As a result, a reverse voltage VR as the reverse bias voltage VRB is applied between the anode terminal 72 and the cathode terminal 74.

The anode potential Va may be 0 V. The reverse voltage VR is a voltage of the cathode potential Vc with the anode potential Va as a reference. In the latent defect detection step (S2), a reverse current IR as the leak current IL is generated between the anode terminal 72 and the cathode terminal 74 due to the reverse voltage VR. In the step of monitoring the leak current IL (S23), the behavior (decrease rate) of the reverse current IR as the leak current IL is monitored (S23). As a result, an initial defect of the device structure 11 having the diode structure Di is detected.

The reverse voltage VR may be a maximum rated reverse voltage or may be less than the maximum rated reverse voltage. The voltage ratio of the reverse voltage VR to the maximum rated reverse voltage may be 0.5 or more and 1 or less. The voltage ratio may have a value belonging to at least one range of 0.5 or more and 0.6 or less, 0.6 or more and 0.7 or less, 0.7 or more and 0.8 or less, 0.8 or more and 0.9 or less, and 0.9 or more and 1 or less. The voltage ratio is preferably 0.8 or more and 1 or less.

The reverse voltage VR may be 500 V or more and 3000 V or less. The reverse voltage VR may have a value belonging to at least one range of 500 V or more and 1000 V or less, 1000 V or more and 1500 V or less, 1500 V or more and 2000 V or less, 2000 V or more and 2500 V or less, and 2500 V or more and 3000 V or less.

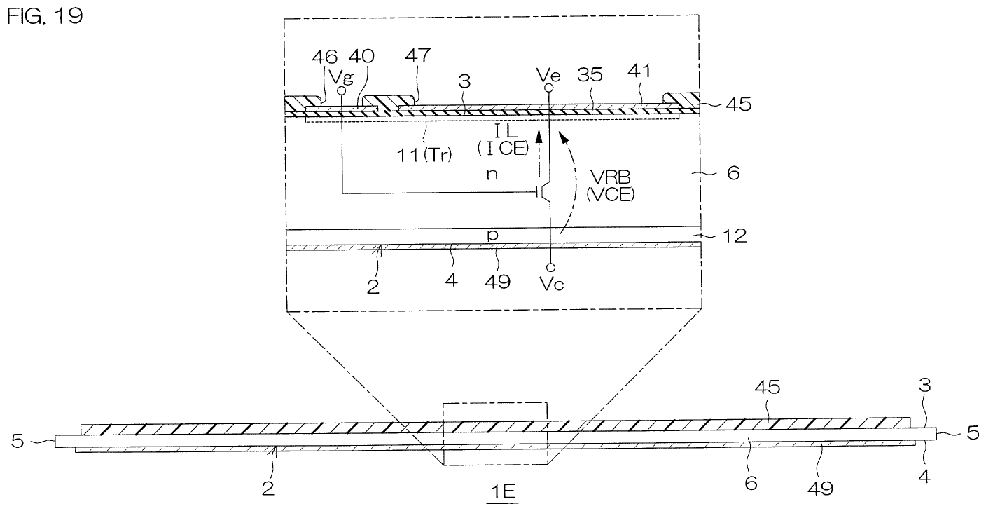

FIG. 19 is a cross-sectional view illustrating a wafer structure 1E according to a fifth embodiment example. Referring to FIG. 19, the wafer structure 1E includes a p-type first semiconductor region 12 instead of the n-type first semiconductor region 12. That is, the wafer structure 1E has an IGBT structure as an example of the transistor structure Tr.

The IGBT structure has a gate, an emitter, and a collector. A specific configuration of the IGBT structure is obtained by replacing “source” with “emitter” and “drain” with “collector” in the description of the above-described embodiments. In the IGBT structure, a gate potential Vg is to be applied to the gate, an emitter potential Ve is to be applied to the emitter, and a collector potential Vc is to be applied to the collector. In the IGBT structure, the reverse bias voltage VRB becomes a collector bias voltage VCE, and the leak current IL becomes a collector cutoff current ICE.

The p-type first semiconductor region 12 may be formed by introducing a p-type impurity into the surface layer portion of the second surface 4 of the n-type wafer 2 (first semiconductor layer 6) by using an ion implantation method. In the case of the IGBT structure, the wafer 2 does not necessarily have the second semiconductor layer 7 (second semiconductor region 13).

The above-described embodiments can be implemented in still other embodiments. For example, in each of the embodiments described above, the latent defect detection step (S2) is performed by using a high temperature reverse bias step. However, the latent defect detection step (S2) is not necessarily performed in a high temperature environment, and may be performed in a normal temperature environment (room temperature environment) or a low temperature environment of 0° C. or lower. That is, the latent defect detection step (S2) may be performed by using a normal temperature reverse bias step or a low temperature reverse bias step.

In each of the embodiments described above, the wafer 2 including the SiC single crystal is adopted. However, the wafer 2 may include a wide bandgap semiconductor single crystal other than the SiC single crystal. For example, the wafer 2 may include gallium nitride, gallium oxide, or diamond, and the like. As a matter of course, the wafer 2 may include a silicon single crystal.

Similarly, the first semiconductor layer 6 may include a wide bandgap semiconductor single crystal other than the SiC single crystal. The first semiconductor layer 6 may include gallium nitride, gallium oxide, diamond, or the like. As a matter of course, the first semiconductor layer 6 may include a silicon single crystal.

Similarly, the second semiconductor layer 7 may include a wide bandgap semiconductor single crystal other than the SiC single crystal. The second semiconductor layer 7 may include gallium nitride, gallium oxide, diamond, or the like. Similarly, as a matter of course, the second semiconductor layer 7 may include a silicon single crystal.

In each of the embodiments described above, the wafer 2 has the notched portion as an example of the mark 5a. However, the mark 5a may have a flat portion including a linearly extending notched portion instead of the notched portion. The flat portion may be referred to as an “orientation flat.” The flat portion may extend along the a-axis direction or the m-axis direction.

In each of the embodiments described above, the wafer 2 having a layered structure including the first semiconductor layer 6 and the second semiconductor layer 7 has been exemplified. However, the wafer 2 does not necessarily have to have the second semiconductor layer 7, and may have a single-layer structure including the first semiconductor layer 6.

In each of the embodiments described above, an example in which the transistor structure Tr and the diode structure Di are formed on different wafers 2 has been described. However, the wafer structures 1A to 1E may include both the device region 8 for the transistor structure Tr and the device region 8 for the diode structure Di in the same wafer 2.

As a matter of course, the device structure 11 may include both the transistor structure Tr and the diode structure Di formed in the same device region 8 in the same wafer 2. In this case, the diode structure Di may be electrically interposed between the source terminal 41 as the anode terminal 72 and the drain terminal 49 as the cathode terminal 74. That is, the diode structure Di may be electrically connected to the transistor structure Tr as a freewheeling diode for the transistor structure Tr.

In each of the embodiments described above, the Schottky barrier diode structure has been described as an example of the diode structure Di. However, the diode structure Di may include at least one of a pn junction diode, a pin junction diode, a Zener diode, and a fast recovery diode.

In these cases, the diode structure Di may include one or a plurality of p-type anode regions forming a pn¥junction with the first semiconductor region 12 and/or the second semiconductor region 13 in the surface layer portion of the first surface 3. Also, the method of manufacturing the semiconductor device 10 and the semiconductor testing device 51 according to each embodiment can be applied to various devices to which the reverse bias voltage VRB can be applied.

In each of the embodiments described above, a structure in which the conductivity type of the “n-type” semiconductor region is inverted to the “p-type” and the conductivity type of the “p-type” semiconductor region is inverted to the “n-type” may be adopted. A specific configuration in this case can be obtained by replacing “n-type” with “p-type” and at the same time replacing “p-type” with “n-type” in the foregoing description and the accompanying drawings.

Hereinafter, examples of features extracted from this description and the attached drawings shall be indicated. Hereinafter, alphanumeric characters and the like in parentheses represent corresponding constituents and the like in each of the above-described embodiments, but are not intended to limit the scope of each clause to one embodiment.
[A1] A method of manufacturing a semiconductor device (10) including a reverse bias test (S2) for a device structure (11), the method comprising: a step (S22) of applying a reverse bias voltage (VRB) to the device structure (11); and a monitor step (S23) of monitoring a decrease rate of a leak current (IL) of the device structure (11) at a time of applying the reverse bias voltage (VRB).
[A2] The method of manufacturing a semiconductor device (10) according to A1, wherein the monitor step (S23) includes a step of determining a latent defect of the device structure (11) on the basis of the decrease rate of the leak current (IL).
[A3] The method of manufacturing a semiconductor device (10) according to A2, wherein the monitor step (S23) includes a step of determining the latent defect on the basis of the decrease rate with an initial value (Iin) of the leak current (IL) as a reference.
[A4] The method of manufacturing a semiconductor device (10) according to A2 or A3, wherein the monitor step (S23) includes a step of determining that the device structure (11) has the latent defect in a case where the decrease rate is 10% or more.
[A5] The method of manufacturing a semiconductor device (10) according to A4, wherein the decrease rate is 20% or more.
[A6] The method of manufacturing a semiconductor device (10) according to any one of A1 to A5, wherein the monitor step (S23) includes a step of monitoring the decrease rate of the leak current (IL) in a monitor period (TM) with a time of starting application of the reverse bias voltage (VRB) as a reference.
[A7] The method of manufacturing a semiconductor device (10) according to A6, wherein the monitor period (TM) is within 60 minutes.
[A8] The method of manufacturing a semiconductor device (10) according to A7, wherein the monitor period (TM) is within 30 minutes.
[A9] The method of manufacturing a semiconductor device (10) according to any one of A1 to A8, wherein the reverse bias test (S2) is a high temperature reverse bias test (S2).
[A10] The method of manufacturing a semiconductor device (10) according to any one of A1 to A9, in which the reverse bias voltage (VRB) is 500 V or more and 3000 V or less.
[A11] The method of manufacturing a semiconductor device (10) according to any one of A1 to A10, wherein the reverse bias test (S2) is a wafer-level test for the device structure (11) formed on a wafer (2).
[A12] The method of manufacturing a semiconductor device (10) according to A11, wherein the wafer (2) includes an SiC single crystal.
[A13] The method of manufacturing a semiconductor device (10) according to any one of A1 to A12, wherein the device structure (11) includes a transistor structure (Tr).
[A14] The method of manufacturing a semiconductor device (10) according to A13, further comprising a gate bias test (S3) for the transistor structure (Tr).
[A15] The method of manufacturing a semiconductor device (10) according to A13, wherein a gate bias test (S3) for the transistor structure (Tr) is not performed.
[A16] The method of manufacturing a semiconductor device (10) according to any one of A13 to A15, wherein the transistor structure (Tr) includes a gate (20, 40), a source (15, 41), and a drain (12, 13, 49), the reverse bias voltage (VRB) is a drain bias voltage (VDS), and the leak current

(IL) is a drain cutoff current (IDS).
[A17] The method of manufacturing a semiconductor device (10) according to any one of A13 to A15, wherein the transistor structure (Tr) includes a gate (20, 40), an emitter (15, 41), and a collector (12, 13, 49), the reverse bias voltage (VRB) is a collector bias voltage (VCE), and the leak current (IL) is a collector cutoff current (ICE).
[A18] The method of manufacturing a semiconductor device (10) according to any one of A1 to A17, wherein the device structure (11) includes a diode structure (Di).
[A19] The method of manufacturing a semiconductor device (10) according to claim 18, wherein the diode structure (Di) has an anode (72) and a cathode (12, 13, 74), the reverse bias voltage (VRB) is a reverse voltage (VR), and the leak current (IL) is a reverse current (IR).
[A20] A method of manufacturing a semiconductor device (10), comprising a step (S2) of monitoring a decrease rate of a leak current (IL) of a device structure (11) at a time of applying a reverse bias voltage (VRB) to a device structure (11), and determining a latent defect of the device structure (11) on the basis of the decrease rate of the leak current (IL).
[B1] A semiconductor testing device (51) performing a reverse bias test (S2) on a device structure (11), the semiconductor testing device (51) comprising: a voltage application unit (54) that applies a test voltage to the device structure (11); a voltage generation unit (55) that generates a reverse bias voltage (VRB) as the test voltage and outputs the reverse bias voltage to the voltage application unit (54); and a control unit (56) that monitors a decrease rate of a leak current (IL) of the device structure (11) at a time of applying the reverse bias voltage (VRB).
[B2] The semiconductor testing device (51) according to B1, wherein the control unit (56) determines the latent defect of the device structure (11) on the basis of the decrease rate of the leak current (IL).
[B3] The semiconductor testing device (51) according to B2, wherein the control unit (56) determines the latent defect on the basis of the decrease rate with an initial value (Iin) of the leak current (IL) as a reference.
[B4] The semiconductor testing device (51) according to B2 or B3, wherein the control unit (56) determines that the device structure (11) has the latent defect in a case where the decrease rate of the leak current (IL) is 10% or more.
[B5] The semiconductor testing device (51) according to B4, wherein the decrease rate is 20% or more.
[B6] The semiconductor testing device (51) according to any one of B1 to B5, wherein the control unit (56) monitors the decrease rate of the leak current (IL) of the device structure (11) in a monitor period (TM) with a time of starting application of the reverse bias voltage (VRB) as a reference.
[B7] The semiconductor testing device (51) according to B6, wherein the monitor period (TM) is within 60 minutes.
[B8] The semiconductor testing device (51) according to B7, wherein the monitor period (TM) is within 30 minutes.
[B9] The semiconductor testing device (51) according to any one of B1 to B8, wherein the reverse bias test (S2) is a high temperature reverse bias test (S2).
[B10] The semiconductor testing device (51) according to any one of B1 to B9, wherein the reverse bias voltage (VRB) is 500 V or more and 3000 V or less.
[B11] The semiconductor testing device (51) according to any one of B1 to B10, wherein the reverse bias test (S2) is a wafer-level test for the device structure (11) formed on a wafer (2).
[B12] The semiconductor testing device (51) according to B11, wherein the wafer (2) includes an SiC single crystal.
[B13] The semiconductor testing device (51) according to any one of B1 to B12, wherein the device structure (11) includes a transistor structure (Tr).
[B14] The semiconductor testing device (51) according to B13, wherein the transistor structure (Tr) has a gate (20, 40), a source (15, 41) and a drain (12, 13, 49), the reverse bias voltage (VRB) is a drain bias voltage (VDS), and the leak current (IL) is a drain bias cutoff current (IDS).
[B15] The semiconductor testing device (51) according to B14, wherein the transistor structure (Tr) has one or both of a trench electrode type gate structure (20) and a planar electrode type gate structure (20).
[B16] The semiconductor testing device (51) according to B14 or B15, wherein the transistor structure (Tr) has a trench electrode type source structure (25).
[B17] The semiconductor testing device (51) according to B13, wherein the transistor structure (Tr) has a gate (20, 40), an emitter (15, 41) and a collector (12, 13, 49), the reverse bias voltage (VRB) is a collector bias voltage (VCE), and the leak current (IL) is a collector cutoff current (ICE).
[B18] The semiconductor testing device (51) according to any one of B1 to B17, wherein the device structure (11) includes a diode structure (Di).
[B19] The semiconductor testing device (51) according to B18, wherein the diode structure (Di) has an anode (72) and a cathode (12, 13, 74), the reverse bias voltage (VRB) is a reverse voltage (VR), and the leak current (IL) is a reverse current (IR).
[B20] A semiconductor testing device (51) monitoring a decrease rate of a leak current (IL) of a device structure (11) at a time of applying a reverse bias voltage (VRB) to the device structure (11) and determining a latent defect of the device structure (11) on the basis of the decrease rate of the leak current (IL).

The method of manufacturing the semiconductor device (10) according to any one of [A1] to [A20] may be a manufacturing method performed in the semiconductor testing device (51) according to any one of [B1] to [B20]. The semiconductor testing device (51) according to any one of [B1] to [B20] may be a testing device that performs the method of manufacturing the semiconductor device (10) according to any one of [A1] to [A20].

The “semiconductor device” according to the above item may be replaced with an “SiC semiconductor device,” a “wide bandgap semiconductor device,” a “semiconductor switching device,” a “MISFET device,” an “IGBT device,” a “semiconductor rectifying device,” or the like, as necessary. The “semiconductor testing device” according to the above item may be replaced with an “SiC semiconductor testing device,” a “wide bandgap semiconductor testing device,” a “transistor testing device,” a “MISFET testing device,” an “IGBT testing device,” a “diode testing device,” or the like, as necessary.

While specific embodiments have been described in detail above, these are merely specific examples used to clarify the technical contents. The various technical ideas extracted from this specification can be combined as appropriate with each other without being limited by the order of description, the order of configuration examples, the order of modification examples, etc., in this specification.

What is claimed is:

1. A semiconductor device manufacturing method including a reverse bias test for a device structure, the method comprising:
a step of applying a reverse bias voltage to the device structure; and
a monitor step of monitoring a decrease rate of a leak current of the device structure at a time of applying the reverse bias voltage.

2. The semiconductor device manufacturing method according to claim 1,
wherein the monitor step includes a step of determining a latent defect of the device structure on the basis of the decrease rate of the leak current.

3. The semiconductor device manufacturing method according to claim 2,
wherein the monitor step includes a step of determining the latent defect on the basis of the decrease rate with an initial value of the leak current as a reference.

4. The semiconductor device manufacturing method according to claim 2,
wherein the monitor step includes a step of determining that the device structure has the latent defect in a case where the decrease rate is 10% or more.

5. The semiconductor device manufacturing method according to claim 4,
wherein the decrease rate is 20% or more.

6. The semiconductor device manufacturing method according to claim 1,
wherein the monitor step includes a step of monitoring the decrease rate of the leak current in a monitor period with a time of starting application of the reverse bias voltage as a reference.

7. The semiconductor device manufacturing method according to claim 6,
wherein the monitor period is within 60 minutes.

8. The semiconductor device manufacturing method according to claim 7,
wherein the monitor period is within 30 minutes.

9. The semiconductor device manufacturing method according to claim 1,
wherein the reverse bias test is a high temperature reverse bias test.

10. The semiconductor device manufacturing method according to claim 1,
wherein the reverse bias voltage is 500 V or more and 3000 V or less.

11. The semiconductor device manufacturing method according to claim 1,
wherein the reverse bias test is a wafer-level test for the device structure formed on a wafer.

12. The semiconductor device manufacturing method according to claim 11,
wherein the wafer includes an SiC single crystal.

13. The semiconductor device manufacturing method according to claim 1,
wherein the device structure includes a transistor structure.

14. The semiconductor device manufacturing method according to claim 13, further comprising:
a gate bias test for the transistor structure.

15. The semiconductor device manufacturing method according to claim 13,
wherein a gate bias test for the transistor structure is not performed.

16. The semiconductor device manufacturing method according to claim 13,
wherein the transistor structure includes a gate, a source, and a drain,
the reverse bias voltage is a drain bias voltage, and
the leak current is a drain cutoff current.

17. The semiconductor device manufacturing method according to claim 13,
wherein the transistor structure includes a gate, an emitter, and a collector,
the reverse bias voltage is a collector bias voltage, and
the leak current is a collector cutoff current.

18. The semiconductor device manufacturing method according to claim 1,
wherein the device structure includes a diode structure.

19. The semiconductor device manufacturing method according to claim 18,
wherein the diode structure has an anode and a cathode,
the reverse bias voltage is a reverse voltage, and
the leak current is a reverse current.

20. A semiconductor testing device performing a reverse bias test for a device structure, the semiconductor testing device comprising:
a voltage application unit that applies a test voltage to the device structure;
a voltage generation unit that generates a reverse bias voltage as the test voltage and outputs the reverse bias voltage to the voltage application unit; and
a control unit that monitors a decrease rate of a leak current of the device structure at a time of applying the reverse bias voltage.
